(19) United States
(12) Patent Application Publication
(10) Pub. No.: US 2005/0195985 A1
(43) Pub. Date: Sep. 8, 2005

(54) Focused parametric array

(75) Inventors: James J. Croft III, San Diego, CA (US); Wensen Liu, San Diego, CA (US)

Correspondence Address: THORPE NORTH & WESTERN, LLP., 8180 SOUTH 700 EAST, SUITE 200, P.O. BOX 1219, SANDY, UT, 84070, US

(73) Assignee: American Technology Corporation

(21) Appl. No.: 11/065,698

(22) Filed: Feb. 24, 2005

Related U.S. Application Data
(63) Continuation-in-part of application No. 09/430,801, filed on Oct. 29, 1999, now Pat. No. 6,850,623.
(60) Provisional application No. 60/547,487, filed on Feb. 25, 2004.

(51) Int. Cl. H04B 3/00; H03G 5/00; H04B 1/02

(52) U.S. Cl. 381/77; 367/137

(57) ABSTRACT

A parametric sound system for creating an acoustical column along an axis of propagation having a quiet zone an audible zone is disclosed. The system comprises a parametric electro-acoustic emitter configured for emitting a plurality of focalized parametric ultrasonic waves. A plurality of decoupled acoustic waves are maximized at a focalizing area within the audible zone. The system also includes a signal source for applying a parametric ultrasonic signal to the parametric electroacoustic emitter. The signal includes an ultrasonic carrier signal and one or more sideband signals corresponding to an audio input signal. The system further comprises a signal processor for controlling phases of the parametric ultrasonic signal so that the plurality of focalized parametric ultrasonic waves emitted by the parametric electro-acoustic emitter will create a quiet zone along the same direction of propagation as the audible zone. The plurality of decoupled audio waves are substantially in phase within the audible zone while the plurality of decoupled audio waves are largely out-of-phase within the quiet zone.

This application is a continuation-in-part of U.S. patent application Ser. No. 09/430,801 filed Oct. 29, 1999 and claims priority to U.S. Provisional Patent Application Ser. No. 60/547,487 filed Feb. 25, 2004, each of which are incorporated herein by reference. This application also claims priority to U.S. patent application Ser. No. 09/850,523 filed May 7, 2001, Ser. No. 10/458,498 filed Jun. 9, 2003, Ser. No. 10/101,426 filed Mar. 18, 2002, U.S. Provisional Patent Application Ser. No. 60/496,834 filed Aug. 21, 2003, and International Patent Application Serial No. PCT/US/00/00 103 filed Jan. 4, 2000, each of which are incorporated herein by reference.

### BACKGROUND OF THE INVENTION

1. Field of the Invention

The present invention relates generally to audio reproduction. More specifically, this invention relates to parametric sound reproduction.

2. Related Art

One of the most unusual distinctions between parametric and conventional sound relates to directionality, a property unique to parametric sound. Despite developments in directional sound, it has not been feasible with either parametric or conventional sound to focus wideband audio signals to a specific location. Conventional loudspeakers have not been able to focus sound in a practical manner because in order to create focused sound propagation, devices of large sizes relative to audio wavelengths are required. As an example, to achieve significant directivity at 200 Hz would require a conventional linear audio transducer system of a diameter many times the approximately 5.65 foot wavelength at that frequency. This would translate to a device at least 11 to 30 feet or more in diameter, and with conventional speakers, a significant amount of enclosure depth would also be required.

Likewise, parametric loudspeakers have had difficulty in creating focused, wideband audio signals. Typical parametric loudspeakers create a beam of propagated sound, as illustrated in FIG. 1a. Ordinarily, the propagated sound 102 emitted from a parametric loudspeaker 104 is substantially collimated, but disperses outwards at an angle of 3°, as shown in FIG. 1a. In addition to the unwanted dispersion of 3°, typical parametric loudspeakers often produce sidelobes which can be detrimental where a narrow beam of sound is desired. Furthermore, the parametric loudspeaker 104 typically is unable to produce high intensities throughout the frequency spectrum. In particular, the lower frequencies are often attenuated as compared to the upper frequencies.

One method of partial focusing of the propagated wave is illustrated in FIG. 1b. While the apparatus 152 in FIG. 1b may be successful in eliminating the dispersion shown in FIG. 1a, the problem of attenuated amplitudes at lower frequencies remains. Furthermore, because parametric loudspeakers have historically been inefficient in their reproduction of middle to low audio frequencies, parametric loudspeakers have been less able to achieve output levels that are competitive with conventional loudspeakers. Parametric loudspeakers typically have too much gain and directivity at high audio frequencies and are deficient at mid-band and low audio frequency output. Essentially, in the parametric loudspeaker prior art, conversion efficiency and low frequency capability has been necessarily sacrificed for sound column directivity.

### SUMMARY OF THE INVENTION

A parametric sound system for creating an acoustical column along an axis of propagation having a quiet zone an audible zone is disclosed. The system comprises a parametric electro-acoustic emitter configured for emitting a plurality of focalized parametric ultrasonic waves. A plurality of decoupled acoustic waves are maximized at a focalizing area within the audible zone. The system also includes a signal source for applying a parametric ultrasonic signal to the parametric electroacoustic emitter. The signal includes an ultrasonic carrier signal and one or more sideband signals corresponding to an audio input signal. The system further comprises a signal processor for controlling phases of the parametric ultrasonic signal so that the plurality of focalized parametric ultrasonic waves emitted by the parametric electro-acoustic emitter will create a quiet zone along the same direction of propagation as the audible zone. The plurality of decoupled audio waves are substantially in phase within the audible zone while the plurality of decoupled audio waves are largely out-of-phase within the quiet zone.

### BRIEF DESCRIPTION OF THE DRAWINGS

The following drawings illustrate exemplary embodiments for carrying out the invention. Like reference numerals refer to like parts in different views or embodiments of the present invention in the drawings.

FIG. 1a is a perspective view of a known parametric speaker.

FIG. 1b is a perspective view of a known parametric speaker configured for focusing its emitted output.

FIG. 2a is a reference diagram for FIGS. 1b and 1c.

FIG. 2b is a block diagram of a conventional audio system.

FIG. 2c is a flow diagram illustrating the complexities of a parametric audio system, and defining the terminology of a parametric audio system.

FIG. 3a is a perspective view of a transducer, in accordance with one embodiment of the invention, wherein the emitter is separated into multiple emission zones.

FIG. 3b is a side view of a transducer, illustrating the convergence of the emitted waves to a focalizing area, in accordance one embodiment of the invention.

FIG. 3c is a front view of a transducer, in accordance with one embodiment of the invention, wherein the emitter is separated into multiple concentric emission zones.

FIG. 3d is a front view of a plurality of bimorph transducers supported by a support member and configured for emitting parametric ultrasonic waves.

FIG. 3e shows an illustration of beam focusing in accordance with an embodiment of the present invention.

FIG. 4a is a chart showing an approximate frequency response of the emitters of the present invention.

FIG. 4b is a chart showing the frequency response of the decoupled audio wave of a conventional parametric loudspeaker compared to the decoupled wave of a parametric loudspeaker in accordance with at least one embodiment of the present invention.

FIG. 4c is an illustration showing an example of a carrier signal at an operating frequency of 40 kHz with a sideband signal, wherein the difference between the carrier signal and the sideband signal is substantially equal to an audio signal, in accordance with an embodiment of the present invention.

FIG. 5a is a side view of a transducer having emission zones on multiple planes, in accordance with one embodiment of the invention.

FIG. 5b is a side view of a transducer having emission zones on multiple planes, in accordance with another embodiment of the invention.

FIG. 5c is a side view of a transducer having emission zones on multiple planes, in accordance with another embodiment of the invention.

FIG. 6a is a front view of a transducer illustrating one technique for coupling the signal sources to the emission zones.

FIG. 6b is a front view of a transducer illustrating another technique for coupling the signal sources to the emission zones.

FIG. 7a is a chart showing an amplitude vs. distance plot of the acoustic output of a typical prior art parametric emitter.

FIG. 7b is a chart showing an amplitude vs. distance plot of the acoustic output of a parametric emitter having an even number of concentric rings, in accordance with one embodiment of the present invention.

FIG. 7c is a chart showing an amplitude vs. distance plot of the acoustic output of a parametric emitter having an odd number of concentric rings, in accordance with one embodiment of the present invention.

FIG. 8a is a schematic diagram of one system used to drive multiple emission zones, in accordance with one embodiment of the present invention.

FIG. 8b is a side view of a piezo-electric film, to further illustrate the schematic diagram of FIG. 8a.

FIG. 8c is a schematic diagram of a second system used to drive multiple emission zones, in accordance with one embodiment of the present invention.

FIG. 8d is a side view of a piezo-electric film, to further illustrate the schematic diagram of FIG. 8c.

FIG. 9 is a flow diagram illustrating a method used for increasing acoustic amplitude at lower audio frequencies for a resultant decoupled audio wave from a parametric loudspeaker.

FIG. 10 is a flow diagram illustrating a method used for creating a wideband focalization of an audio wave.

FIG. 11 is a flow diagram illustrating a method used for shortening an audio column length of a parametric loudspeaker when used in an air medium.

FIG. 12 is an illustration of one use for the present invention, wherein the emitters disclosed herein are configured for creating a virtual headset.

FIG. 13a is a perspective view of a room wherein predefined audible zones and predefined quiet zones coexist, in accordance with one embodiment of the present invention.

FIG. 13b is a side view of a propagated parametric ultrasonic wave, in accordance with one embodiment of the present invention, wherein a quiet zone is interposed between, and along the same direction of propagation as at least two audible zones.

FIG. 13c is a side view of a propagated parametric ultrasonic wave, in accordance with one embodiment of the present invention, wherein a quiet zone directly follows, and is along the same direction of propagation as an audible zone.

FIG. 14 is a flow diagram, illustrating a method used for creating predefined audible zones within the same listening area as predefined quiet zones.

### DETAILED DESCRIPTION

Reference will now be made to the exemplary embodiments illustrated in the drawings, and specific language will be used herein to describe the same. It will nevertheless be understood that no limitation of the scope of the invention is thereby intended. Alterations and further modifications of the inventive features illustrated herein, and additional applications of the principles of the inventions as illustrated herein, which would occur to one skilled in the relevant art and having possession of this disclosure, are to be considered within the scope of the invention.

Because parametric sound is a developing field, and in order to identify the distinctions between parametric sound and conventional audio systems, the following definitions, along with explanatory diagrams, are provided. While the following definitions may also be employed in future applications from the present inventor(s), the definitions are not meant to retroactively narrow or define past applications or patents from the present inventor(s), their associates, or assignees.

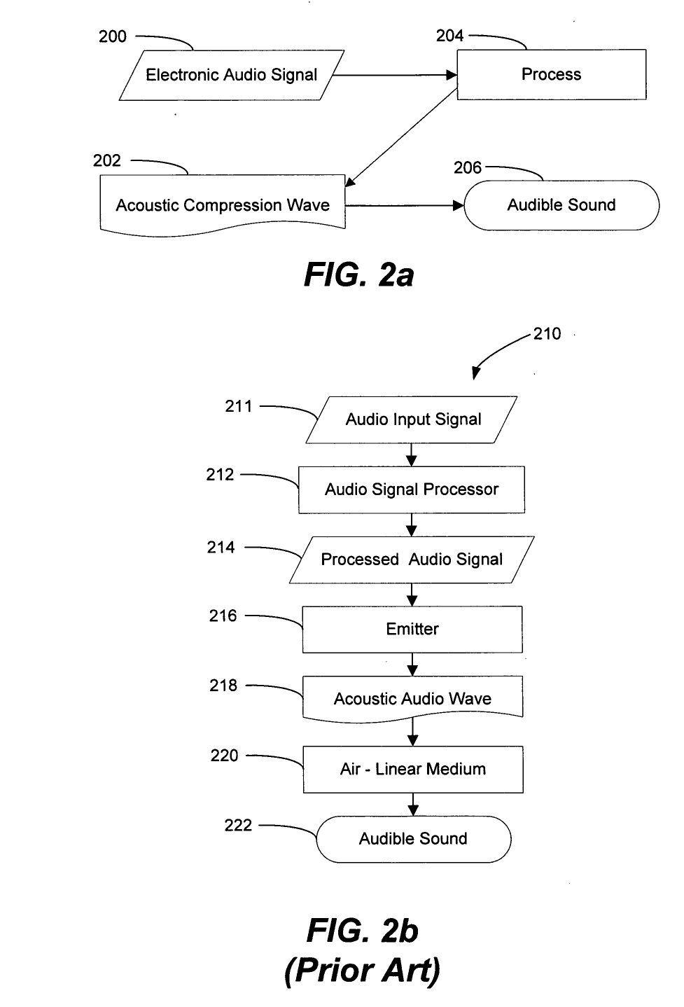

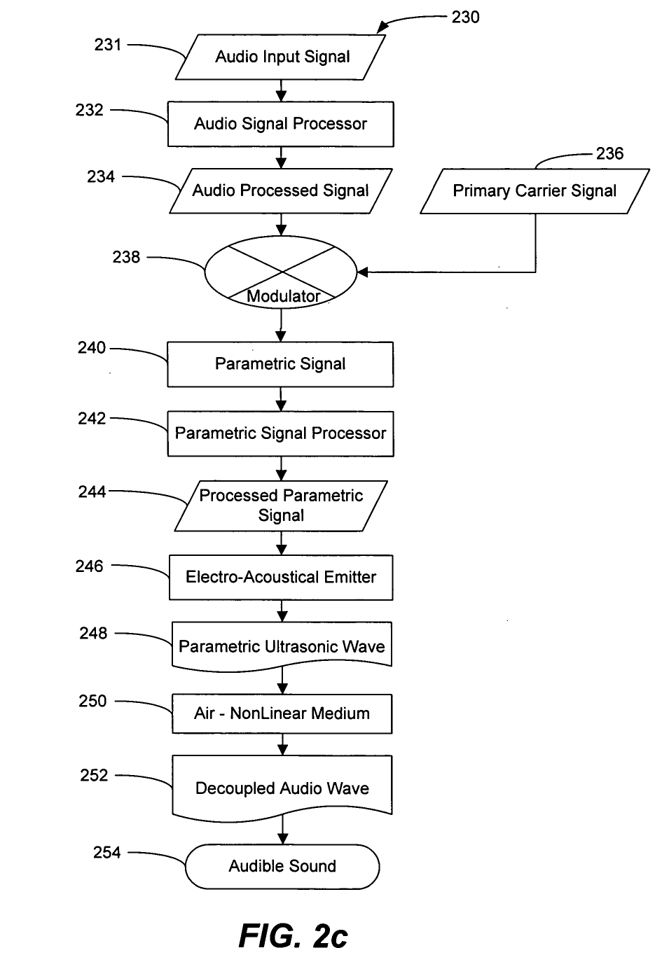

FIG. 2a serves the purpose of establishing the meanings that will be attached to various block diagram shapes in FIGS. 2b and 2c. The block labeled 200 can represent any electronic input audio signal. Block 200 will be used whether the audio signal corresponds to a sonic signal, an ultrasonic signal, or a parametric ultrasonic signal. Throughout this application, any time the word ‘signal’ is used, it refers to an electronic representation of an audio component, as opposed to an acoustic compression wave.

The block labeled 202 will represent any acoustic compression wave. An acoustic compression wave is propagated into the air, as opposed to an audio signal, which is in electronic form. The block 202 representing acoustic compression waves will be used whether the compression wave corresponds to a sonic wave, an ultrasonic wave, or a parametric ultrasonic wave. Throughout this application, any time the word ‘wave’ is used, it refers to an acoustic compression wave which is propagated into the air.

The block labeled 204 will represent any process that changes or affects the audio signal or wave passing through the process. The audio passing through the process may either be an electronic audio signal or an acoustic compression wave. The process may either be an artificial process, such as a signal processor or an emitter, or a natural process such as an air medium.

The block labeled 206 will represent the actual audible sound that results from an acoustic compression wave. Examples of audible sound may be the sound heard in the ear of a user, or the sound sensed by a microphone.

FIG. 2b is a flow diagram 210 of a conventional audio system. In a conventional audio system, an audio input signal 211 is supplied which is an electronic representation of the audio wave to be reproduced. The audio input signal 211 may optionally pass through an audio signal processor 212. The audio signal processor is usually limited to linear processing, such as the amplification of certain frequencies and attenuation of others. The audio signal processor 212 may apply non-linear processing to the audio input signal 211 in order to adjust for non-linear distortion that may be directly introduced by the emitter 216. If the audio signal processor 212 is used, it produces a processed audio signal 214.

The processed audio signal 214 or the audio input signal 211 (if the audio signal processor 212 is not used) is then emitted from the emitter 216. As previously discussed, conventional sound systems typically employ dynamic speakers as their emitter source. Dynamic speakers are typically comprised of a simple combination of a magnet, voice coil and cone. The magnet and voice coil convert the variable voltage of the processed audio signal 214 to mechanical displacement, representing a first stage within the dynamic speaker as a conventional multistage transducer. The attached cone provides a second stage of impedance matching between the electrical transducer and air envelope surrounding the emitter 216, enabling transmission of small vibrations of the voice coil to emerge as expansive acoustic audio waves 218. The acoustic audio waves 218 proceed to travel through the air 220, with the air substantially serving as a linear medium. Finally, the acoustic audio wave reaches the ear of a listener, who hears audible sound 222.

FIG. 2c is a flow diagram 230 that clearly highlights the complexity of a parametric sound system as compared to the conventional audio system of FIG. 2b. The parametric sound system also begins with an audio input signal 231. The audio input signal 231 may optionally pass through an audio signal processor 232.

The processed audio signal 234 or the audio input signal 231 (if the audio signal processor 232 is not used) is then modulated with a primary carrier signal 236 using a modulator 238. The primary carrier signal 236 may be supplied by a primary signal source. The primary signal source for a parametric sound system is typically an ultrasonic signal source. However, it is also possible to use a sonic signal source.

While the primary carrier signal 236 is normally fixed at a constant frequency, it is possible to have a primary carrier signal that varies in frequency. The modulator 238 is configured to produce a parametric signal 240, which is comprised of a carrier signal, which is normally fixed at a constant frequency, and at least one sideband signal, wherein the sideband signal frequencies vary such that the difference between the sideband signal frequencies and the carrier signal frequency are the same frequency as the audio input signal 231. The modulator 238 may be configured to produce a parametric signal 240 that either contains one sideband signal (single sideband modulation, or SSB), or both upper and lower sidebands (double sideband modulation, or DSB). Alternatively, the modulator 238, or a filter used in conjunction with the modulator, can produce an output having a suppressed carrier signal, wherein the SSB or DSB signal is substantially the only output. The SSB or DSB signal output of the modulator can then be combined with the primary carrier signal 236 to produce a parametric signal.

The parametric signal 240 may optionally pass through a parametric signal processor 242. The parametric signal processor can be used to amplify or attenuate the sideband and/or primary carrier signals in the parametric signal. Additional signal processing may also occur to adjust for non-linear distortion which may occur at the electro-acoustical emitter 246, the nonlinear medium 250, or when the audio wave decouples 252. If the parametric signal processor is used, it produces a processed parametric signal 244.

The processed parametric signal 244 is then emitted from the electro-acoustical emitter 248, producing a parametric wave 248 which is propagated into the air or nonlinear medium 250. The parametric wave 248 is comprised of a carrier wave and at least one sideband wave. The parametric ultrasonic wave 248 can drive the air into a substantially non-linear state. Air is typically linear at lower amplitudes and frequencies. However, at higher amplitudes and higher frequencies, air molecules don't respond in synchronization with the device producing the waves (i.e. a speaker, transducer, or emitter) and non-linear effects can occur. The air can serve as a non-linear medium, wherein acoustic heterodyning can occur on the parametric wave 248, causing the ultrasonic carrier wave and the at least one sideband wave to decouple in air and produce a decoupled audio wave 252 whose frequency is the difference between the carrier wave frequency and the sideband wave frequencies. Finally, the decoupled audio wave 252 reaches the ear of a listener, who can hear audible sound 254. The end goal of parametric audio systems is for the decoupled audio wave 252 to closely correspond to the original audio input signal 231, such that the audible sound 254 is ‘pure sound’, or the exact representation of the audio input signal. However, because of the nature of parametric loudspeaker technology, including the difficulty of producing a decoupled audio wave 252 having significant intensity over a wide band of audio frequencies, attempts to produce ‘pure sound’ with parametric loudspeakers have been limited. The above process describing parametric audio systems is thus far substantially known in the prior art.

The present invention introduces an apparatus and method for producing a focalized, wideband decoupled audio wave 252 through use of a specialized parametric loudspeaker. Speakers can be used to focus sound to a specific area in a closed environment such as a building. However, even focused sound can reflect off of surfaces, causing it to be heard in unintended locations. Focalizing refers to a speaker capable of producing focused sound in a localized area. Focalizing can minimize or eliminate reflection of focused sound.

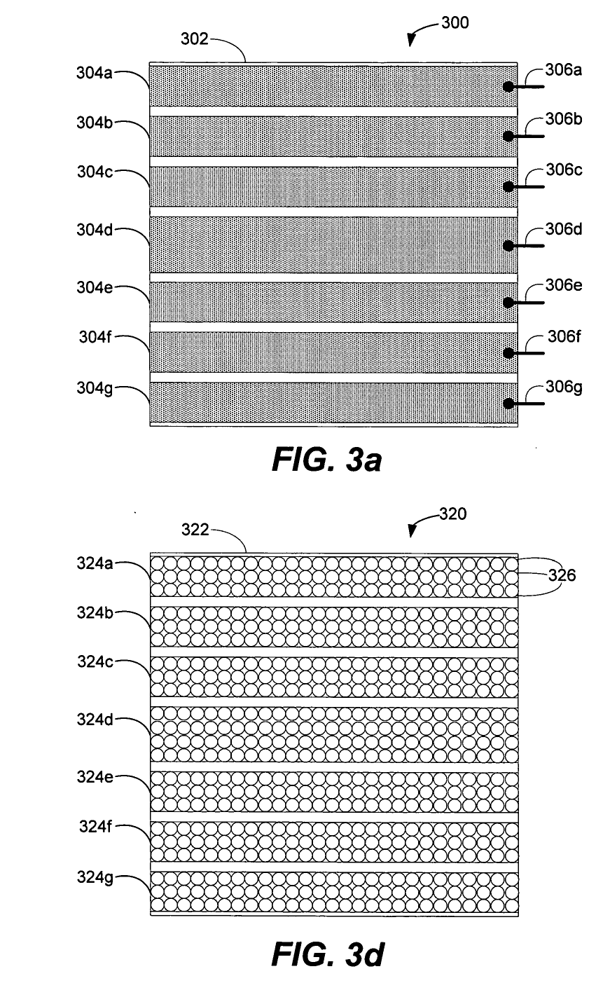

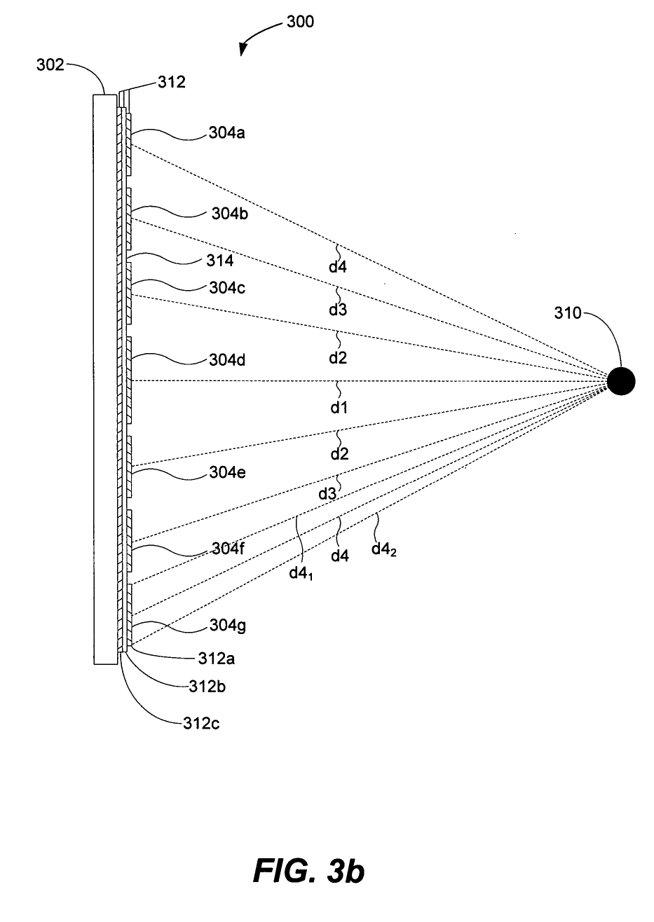

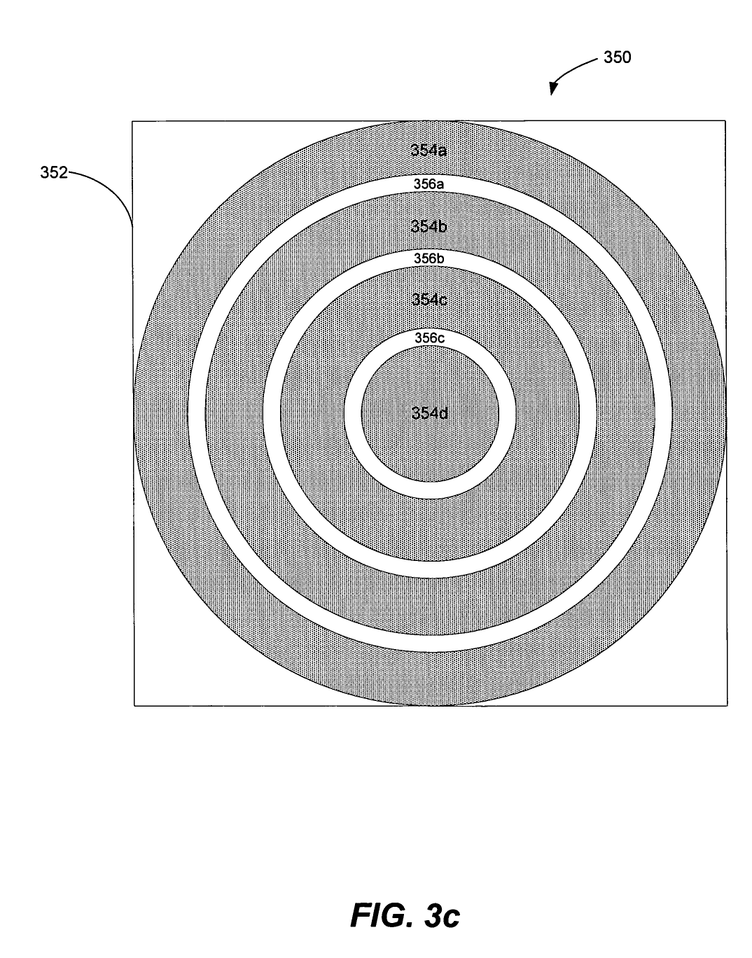

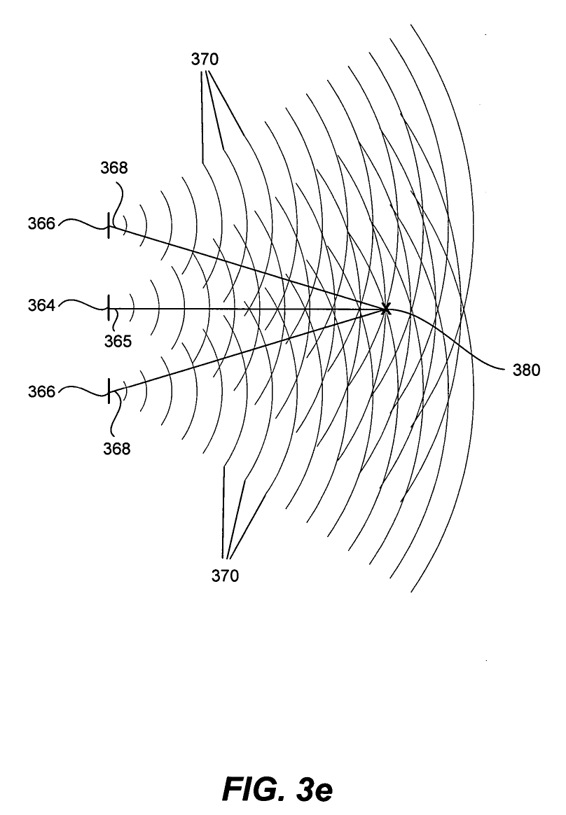

As illustrated in FIG. 3a, a system, indicated generally at 300, in accordance with the present invention, is shown for increasing acoustic amplitude at lower audio frequencies at a predetermined area in space, called the “focalizing area.” The system 300 includes a support member 302 capable of supporting the emission zones 304a-g. The electro-acoustic emitter has a series of adjacent isolated emission zones 304a-g. Each adjacent isolated emission zone is coupled to a signal source 306a-g, which supplies parametric ultrasonic signals to each adjacent isolated emission zone. In the configuration shown in FIG. 3a, the adjacent isolated emission zones are configured to have a center isolated conductive emission strip 304d and a plurality of parallel emission strips (304a, b, c, e, f, and g) on both sides of the center strip 304d, and located at progressively further distances from the center emission strip 304d. Because the emissions zones are configured into parallel strips, the focalizing area results in a line of sound. For example, the focalizing area 310 of FIG. 3b would actually be a line of sound extending into the page, and parallel to the emission zone strips 304a-g.

A simple example of electronic beam focusing is shown in FIG. 3e. A center emission zone 364 can emit sound waves, or wavefronts 370 represented by parabolic lines, into the surrounding medium. Similarly, the outer emission zones 366 emit sound waves into the surrounding medium. The sound waves from each of the emission zones interact, resulting in waves adding and subtracting. The waves can interfere, or add and subtract, depending upon each of the interacting wave's phase. If the waves are in phase they can constructively interfere, or add, to create a larger wave. If the waves are out-of-phase with one another they can destructively interfere, or subtract, resulting in the creation of a smaller wave, or a wave having a smaller amplitude or volume. In the present example the waves are shown to add when the wavefronts 370 cross.

By controlling the phase of the waves as they are emitted from each of the emission zones 364 and 366, the locations where the waves add and subtract can be controlled. In the present example, the phase of the emission zones can be adjusted so that the waves will add constructively at a focus point 380. The center path length 365 between the center emission zone 364 and the focus point can be determined. The center emission zone can be configured to emit sound waves starting at a predetermined phase, such as zero degrees. The outer path length 368 from the outer emission zones 366 to the focus point can then be determined. The difference in path length can be compensated for by physically moving the emitter source so that the phases match, or by electronically altering the phase of the sound waves emitted from the outer emitters with respect to the sound waves emitted by the center emission zone.

For example, the difference in path length between the center path length 365 and the outer path lengths 368 may be three inches. Thus, the sound waves emitted from the outer emission zones 366 will have to travel three inches further than the sound waves from the center emission zone 364. The wavelength of sound can be determined according to the equation:

$$λ = \frac{{V}_{s}}{f} ,$$

wherein λ is the wavelength of the sound, Vₛ is the velocity of sound in air, and f is the frequency of the sound. At sea level, the velocity of sound in air is approximately 1130 feet per second. Thus, for sound waves produced at a frequency of 2,260 Hz, the wavelength of the sound is 0.5 feet, or six inches. A full wave consists of a wave varying in phase from 0 degrees to 360 degrees. Thus, by offsetting the outer path length by a phase of half a wavelength, or 180 degrees, the extra three inch path length traveled by the sound waves emitted from the outer emission zones is compensated for, allowing sound from all three emission zones to reach the focal point 380 when the sound waves are in phase. The in phase waves can add, or constructively interfere, at the focal point. Similarly, the focal point can be moved to a different location by adjusting the phase of the emission zones. Moving the desired focal point where the waves constructively interfere by electrically changing the phase of one or more of the emission zones is often referred to as beam steering.

Returning to FIG. 3b, which is a side view of the embodiment shown in FIG. 3a, the electro-acoustic emitter 300 can be configured such that the parametric ultrasonic waves emitted from each emission zone 304a-g will arrive at the focalizing area 310 within a 90° phase difference of each other. The location of the focalizing area 310 is a function of the phases of each parametric ultrasonic signal applied to each isolated emission zone and the distance of each isolated emission zone relative to the focalizing area, as previously discussed. Each of the emission zones can be arranged such that the distance between the emission zone and the focalizing area d1-d4 can be approximately equal to a multiple of the wavelength (λ).

The wavelength at 40 kHz is approximately 1/3 of an inch. So the distances between each emission zone and the focalizing area can be a multiple of ⅓ of an inch. For example, d1, as measured from the emission zone center, can have a distance of about 10 inches (30×), d2 can be 11 inches (33λ), d3 can be 12 inches (36λ), and d4 can be 13 inches (39λ). Because of the width of the emission zones, the distance from first side d4₁ of an emission zone 304g to the focalizing area can be slightly different than the distance from a second, opposite side d4₂ of the emission zone to the focalizing area. The variation in distance, which depends upon the width of the emission zones, can cause the waves to arrive at the focalizing area within a phase range, rather than in phase. For example, the first side d4₁ of emission zone 304g may be 1/24 of an inch closer to the focalizing area than the center distance d4. Similarly, the second side of emission zone 304g may be 1/24 of an inch farther from the focalizing area than the center distance d4. Thus, with a wavelength of ⅓ of an inch, the acoustic waves from the first side will arrive at the focalizing area 45° in front of the center acoustic waves. The acoustic waves from the second side will arrive at the focalizing area 45° behind the center acoustic waves. In actuality, due to the width of the emission zone, there will be a 90° phase difference in the acoustic waves arriving at the focalizing area from emission zone 304g. The other emission zones can have a similar range of phases from the acoustic waves they emit. The range can enable a larger focalizing area, rather than a pinpoint focalizing point.

As with all parametric speakers, the emitted parametric waves are produced at a sufficient level to drive the surrounding air into nonlinearity. Consequently, the two components of the parametric ultrasonic wave (the ultrasonic carrier wave and the sideband waves) can decouple in air to produce a decoupled audio wave having a frequency equal to the difference of the ultrasonic carrier and the sideband frequencies. By configuring the phases of the parametric ultrasonic signals and sizes of the emission zones such that all emitted parametric ultrasonic waves will arrive at the focalizing area 310 within a 90° phase difference of one another, the decoupled audio wave will have maximum intensity at the focalizing area 310.

In another embodiment of the invention, illustrated in FIG. 3c, the adjacent isolated emission zones can be configured to have a central circular isolated emission zone 354d and at least one concentric outer-ring isolated emission zone 354a, 354b, and 354c. Each emission zone is associated with a concentric conductive emission strip 356a, 356b, and 356c. The concentric emission zones and related conductive emission strips can be configured to form a phased ring emitter 350. Each conductive emission strip can be used to drive an associated emission zone. The emission zones can be driven by applying an electrical signal through the conductive emission strips to each emission zone. The electrical signal can correspond to the parametric ultrasonic signal. As more outer-ring isolated conductive emission zones are added, the decoupled audio wave is capable of being focused to a more precise location in space. Instead of having a localizing area that results in a line of sound, as possessed by the configuration in FIG. 3a, the configuration of FIG. 3c can result in a small focalizing area that is represented generally by a point or area in space. The location of the focalizing area is a function of the phases of each parametric ultrasonic signal applied to each isolated emission zone and the radii of the outer and inner bounds of each isolated emission zone.

The phased ring emitter 350 can operate with a plurality of adjacent emission zones designed such that each emission zone has a periodic change in phase from the adjacent zone, such as 45 degrees, 90 degrees, or 180 degrees. For example, the phased ring emitter of FIG. 3c can be designed such that each ring will have an acoustic output 180 degrees out-of-phase from the adjacent rings. A 180 degree phase shift is equivalent to a distance of half a wavelength. The distance between the inner ring 354d and a predetermined focal point can be a multiple of the wavelength (λ). The distance between the adjacent ring 354c and the predetermined focal point can be an odd multiple of half the wavelength (λ/2, 3λ/2, 5λ/2, . . . , n λ/2, where n is an odd integer). Constructing the phased ring emitter in this manner will enable the waves emitted by the rings to arrive at the selected focal point substantially in phase.

Because phased ring emitters are constructed according to a particular wavelength, phased ring emitters can typically only efficiently focus waves of one particular frequency.

A greater frequency will have a shorter wavelength, and vice versa. The frequency at which a phased ring emitter is designed to operate will be referred to in the present application as the “operating frequency” of the phased ring emitter. Because phase is dependent on frequency, emitted waves outside of the operating frequency of the phased ring emitter will not arrive at the focalizing area in phase with the waves emitted at the operating frequency. Consequently, these waves will sound attenuated to a listener as compared to the waves at the operating frequency.

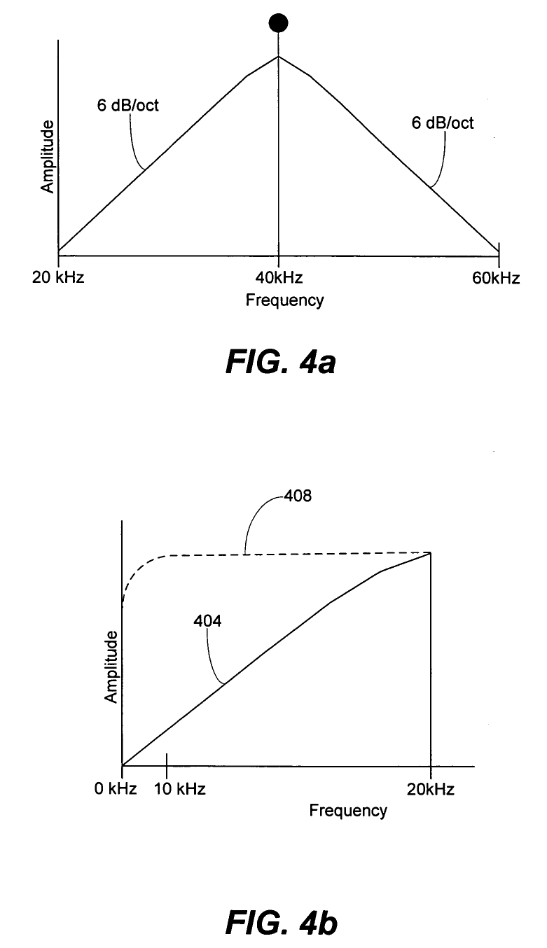

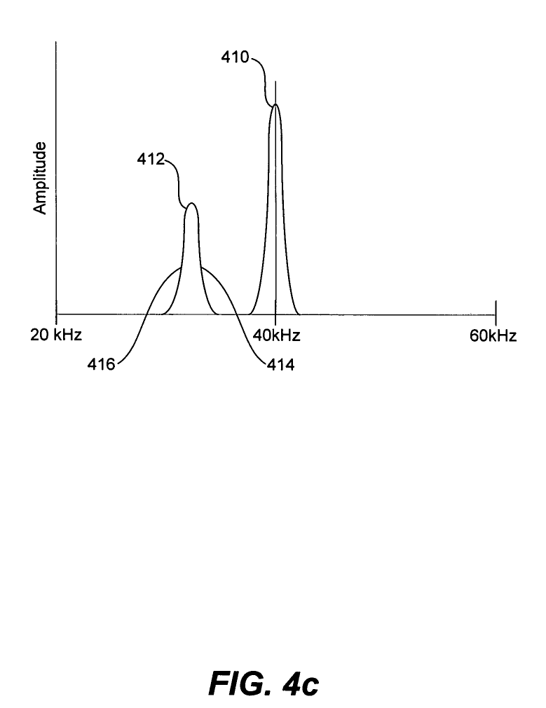

As waves depart from the operating frequency, their amplitudes at the focalizing area are attenuated at a rate of approximately 6 dB per octave, as displayed in FIG. 4a, where, for example, the operating frequency is at 40 kHz. Because phased ring emitters have only been known to be efficient around a narrow frequency (the operating frequency), they have been thought to be unfit for audio reproduction, which typically requires a wide spectrum of frequencies. The same is true for other shapes of phased emitters, wherein the phased emitter has a plurality of emission zones, with each emission zone having a periodic change in phase from the adjacent zone.

The present inventors have found that the same properties that have previously been reason to avoid the use of phased emitters in audio production can yield unexpectedly beneficial results when applied to parametric speakers. This is because parametric speakers operate in a unique manner as compared to conventional audio speakers, as described in detail in the background section.

In particular, there are three main areas where the unique properties of parametric speakers benefit when employed in a phased emitter configuration such as FIGS. 3a and 3c. First, while the narrow frequency response shown in FIG. 4a has been reason to avoid using phased emitters for audio purposes in the past, this frequency response is actually quite beneficial when used to produce parametric sound. Normally, when parametric ultrasonic waves interact in air to create a decoupled audio wave, the low frequencies of the decoupled audio wave are attenuated at approximately 12 dB per octave, as illustrated by the solid line 404 of FIG. 4b. The reason for this drop off in amplitudes at low frequencies is simply that the nonlinear interaction of waves is not as efficient at reproducing lower “bass” frequencies. However, when parametric ultrasonic waves are emitted from the transducer of FIG. 3a or 3c, having a frequency response similar to FIG. 4a, the attenuation of the lower “bass” frequencies is largely eliminated.

As illustrated in FIG. 4C, the reduced attenuation is a result of the nature of the phased emitter having the carrier signal 410 set at the “operating frequency” (40 kHz) of the emitter. The audible sound from a parametric speaker is created by a heterodyning of the carrier signal and the sideband signal in air to create a difference signal substantially equal to the audio. Since the upper sideband frequencies 414 in the sideband signal are closer to the carrier signal, the difference between the carrier signal and the upper frequencies will be the less than the difference between the carrier signal and the lower sideband frequencies 416. The portion of the sideband signal 412 that is closest to the carrier signal corresponds to the lower “bass” frequencies in the decoupled audio wave. Likewise, the frequencies in the sideband signal that are furthest from the carrier signal correspond to the upper “treble” frequencies in the decoupled audio wave.

Returning to FIG. 4a, the further a signal is located from the operating frequency, the more attenuated it will become. The acoustic waves produced by the upper sideband frequencies 414 near the carrier signal can arrive at the focalizing area having greater phase alignment than the acoustic waves produced by the lower sideband frequencies 416 that are located further from the carrier wave. Consequently, the acoustic waves produced by the upper sideband frequencies (the bass frequencies) can arrive at the focalizing area having greater amplitude than the acoustic waves produced by the lower sideband frequencies (the treble frequencies). This is due to the attenuation caused by the lower sideband frequencies being located further from the carrier wave frequency which causes the acoustic waves to be further out-of-phase in the focalizing area. As the phase difference in the acoustic waves increases towards 180°, the destructive interference between the acoustic waves will increase in the focalizing zone. The destructive interference among acoustic waves will decrease the overall amplitude of the resulting waves. Theoretically, acoustic waves arriving at the focalizing area that are 180° out-of-phase will cancel each other out and produce no sound.

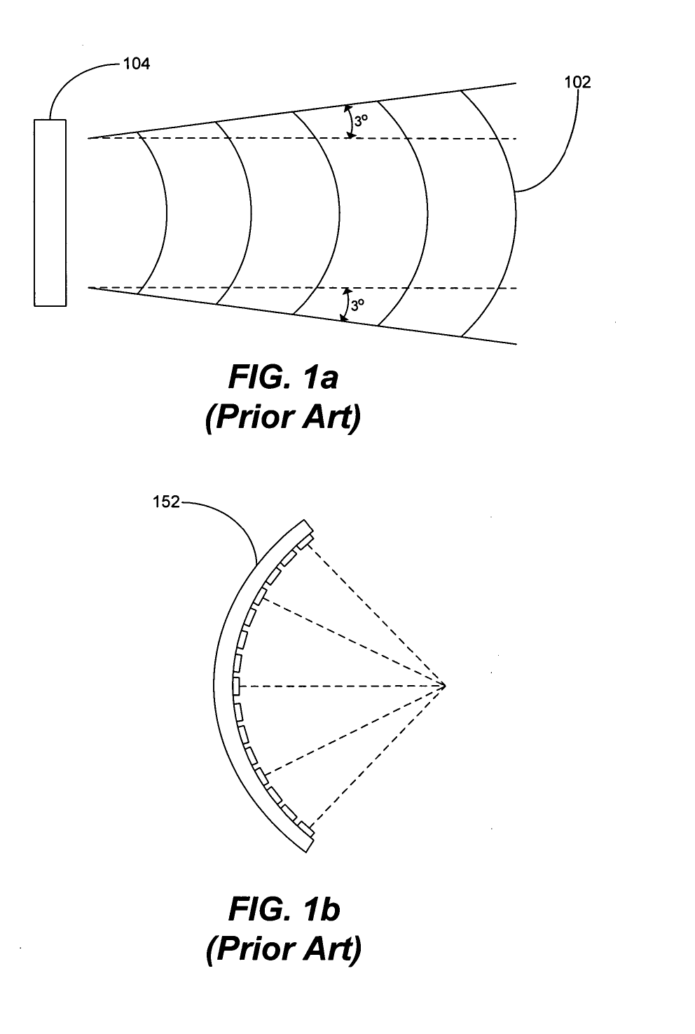

As a result, the corresponding lower bass frequencies of the decoupled audio wave will be amplified when compared to the upper treble frequencies. The attenuation of the upper treble frequencies will offset the natural attenuation of lower bass frequencies (see FIG. 4b) that occurs during the acoustic heterodyning process. The resultant decoupled audio wave will have a frequency response that has increased amplitude at lower audio frequencies, as indicated by the dotted line 408 in FIG. 4b. Increased amplitude is defined as an improvement over the typical poor low-frequency reproduction of typical parametric loudspeakers, as illustrated by the solid line 404 of FIG. 4b. Furthermore, the present invention offers an improvement over focusing parametric loudspeakers such as 152 of FIG. 1b. While a previously produced focusing parametric loudspeaker 152 may focus the decoupled output wave, it does so without the phase shifting techniques employed in the present invention, and therefore does not benefit from the same type of increased amplitude at lower audio frequencies.

As a second benefit, when a parametric ultrasonic wave is emitted from a typical parametric loudspeaker and decouples in the air to form a decoupled audio wave, a large amount of power is used to generate the carrier frequency. When the emitters and methods of the present invention are employed, the carrier frequency is set to the operating frequency of the phased emitter speaker. Because the phased emitters in FIGS. 3a and 3c are most efficient at the operating frequency, the power generated for the carrier frequency is even greater than in standard parametric loudspeakers, resulting in a more efficient system. A third benefit is that typical parametric loudspeakers that generate a focused, decoupled output wave tend to focus the high frequencies so tightly that they are largely impractical to use because the higher frequencies of the decoupled output wave can only be heard in such a limited area in space. When the emitters of the present invention are employed, the higher frequencies of the decoupled output wave are audible over a large enough area (the focalizing area) that it can be put to many practical uses.

In another embodiment, the operating frequency of the emitter may be offset from an emitter's resonant frequency by a predetermined offset frequency. Certain types of emitters operate most efficiently at the emitter's resonant frequency. However, the frequency range around the resonant frequency can have a high rate of change of phase. Thus, separate emitters operating at slightly different resonant frequencies can have significantly different phases. Differences in phase between emitters can cause destructive interference and lead to reduced overall efficiency in the focalizing area. Therefore, the operating frequency of the phased emitter can be offset from the resonant frequency of each emitter. This will enable the acoustic output from a plurality of emitters to be more in phase, enabling greater constructive interference in the focalizing area. While each emitter will not be operating at its peak efficiency, the combined acoustic output of an array of phased emitters can have its maximum efficiency when the operating frequency is offset from the resonant frequency of the emitters by a predetermined amount. Consequently, the decoupled output wave will have a maximum increased amplitude at the predetermined offset frequency.

In one embodiment, the emission zones can be comprised of a film emitter. Various types of film may be used as the emitter film. The important criteria are that the film be capable of responding to an applied electrical signal to constrict and extend in a manner that reproduces an acoustic output corresponding to the signal content. Although piezoelectric materials are the primary materials that supply these design elements, new polymers are being developed that are technically not piezoelectric in nature. Nevertheless, the polymers are electrically sensitive and mechanically responsive in a manner similar to the traditional piezoelectric compositions. Accordingly, it should be understood that references to piezoelectric films in this application are intended to extend to any suitable film that is both electrically sensitive and mechanically responsive (ESMR) so that acoustic waves can be realized in the subject transducer.

An example of a focusing parametric transducer illustrated in FIG. 3c will now be provided. This example transducer is designed to create a focalizing area at 36 inches from the front surface of the transducer, using a carrier frequency of 46 kHz. The ESMR film is mounted on a 14″ square support member. The emission zones have radii of 2.3″ (inner circle), 4″, 5.16″, 6.1″, 6.9″, and 7.68″ (extending the edges of the support member, and being cut off on the edges). To achieve maximum output and focus at the 36 inch distance, the emission zones are phased such that the center portion and each odd numbered section/ring are at zero phase reference and each even ordered section/ring is operated 180 degrees out-of-phase compared to the zero phase reference.

The emission zones of the present invention may be comprised of a variety of emitter types. For example, in one embodiment, illustrated in FIG. 3d, each emission zone 324a-g is comprised of a plurality of bimorph transducers 326 supported by a support member and configured for emitting parametric ultrasonic waves. Each emission zone 324a-g can have the plurality of bimorph transducers 326 configured to have a substantially similar phase.

In one embodiment of the invention, all adjacent isolated emission zones are positioned on a single plane, as illustrated in FIGS. 3a and 3c. In this configuration, the phases of the parametric ultrasonic signals applied to each adjacent isolated emission zone are varied to ensure that the phases of the majority of the parametric ultrasonic waves emitted from the emission zones arrive within 90° of one another at the predetermined area (the focalizing area). For example, the parametric ultrasonic signal can be applied to a center isolated emission zone (304d of FIGS. 3a and 354d of FIG. 3c) at 0° phase, and the phases applied to each successive outer adjacent emission zone are alternated between 180° out-of-phase and 0° phase. Therefore, to use FIG. 3a as an example, the isolated emission strips 304b and 304f would also be set at 0° phase, while emission strips 304a, 304c, 304e, and 304g would be set at 180° out-of-phase. In FIG. 3c, the emission zone 354b and 354d would be set to 0° phase and the emission zones 354a and 354c would be set to 180° out-of-phase. Alternatively all of the above mentioned phases could be reversed, setting the center emission zone to 180° out-of-phase, and alternating each subsequent outer emission zone between a phase of 0° and 180°. A technique that may be used to implement the above embodiment is to run the 180° signals through an inverter prior to applying the signal to the emission zones.

In another embodiment of the invention, the parametric ultrasonic signal is applied to a center isolated emission zone at a phase of 0°, and the phase of the parametric ultrasonic signal applied to each successive outer adjacent emission zone is incremented by 90°. For example, in FIG. 3a, emission strip 304d would be set to a phase of 0°, strips 304e and 304c would be shifted 90° out-of-phase with the center emission zone, strips 304b and 304f would be set at 180° out-of-phase with the center emission zone, 304a and 304g would be set at 270° out-of-phase with the center emission zone, and assuming there were an additional exterior strip on the top and on the bottom of the emitter 300, they would be set at 360° out-of-phase (or 0° phase).

In FIG. 3c, the emission zone 354d would be set at 0° phase, emission zone 354c would be set at 90° phase, emission zone 354b would be set at 180° phase, emission zone 354a would be set at 270° phase, and assuming there was an additional concentric emission zone on the exterior of the emitter 350, it would be set at 360° phase (or 0° phase). Because the phase increments are only 90° (or ¼λ) in the present example instead of the 180° (or ½λ) increments in the previous example, the sizes of each emission zone will have to be adjusted in order to ensure that the majority of the parametric ultrasonic waves emitted from the emission zones will still arrive at the focalizing area within 90° of one another.

In another embodiment of the invention, the parametric ultrasonic signal is applied to a center isolated emission zone at 0° phase, and the phase of the parametric ultrasonic signal applied to each successive outer adjacent emission zone is incremented by 45°. For example, in a concentric emitter such as FIG. 3c, the center emission zone would be set at 0° phase, the first outer emission zone would be set at 45°, the following outer emission zone would be set at 90°, the following outer emission zone would be set at 135°, the following outer emission zone would be set at 180°, the following outer emission zone would be set at 225°, the following outer emission zone would be set at 270°, the following outer emission zone would be set at 315°, the following outer emission zone would be set at 360° (0° phase), and so on. Because the phase increments are only 45° in the present example, the sizes of each emission zone will have to be adjusted in order to ensure that the majority of the parametric ultrasonic waves emitted from the emission zones will still arrive at the focalizing area within 90° of one another.

The phase differentials of the signals applied to each emission zone in the above examples may be implemented by employing phase delays, inverters (to create a 180° phase shift), or a combination of both.

In another embodiment of the invention, the parametric sound system can include a switch for disabling the phase differentials of the parametric ultrasonic signals applied to each emission zone. When the phase differentials are disabled, all signals are applied to the emission zones at a 0° phase differential. Because the parametric ultrasonic waves will be emitted uniformly, the parametric ultrasonic wave will not be focalized to the predetermined focalizing area, and instead will be propagated as a more dispersed column of sound.

As a further variation, the switch may be capable of fading gradually between the original phase differentials and a 0° phase differential. The fading switch can enable a user to gradually shift the parametric ultrasonic wave between a focalized wave at the focalizing area and a non-focalized wave that is a more dispersed column of sound.

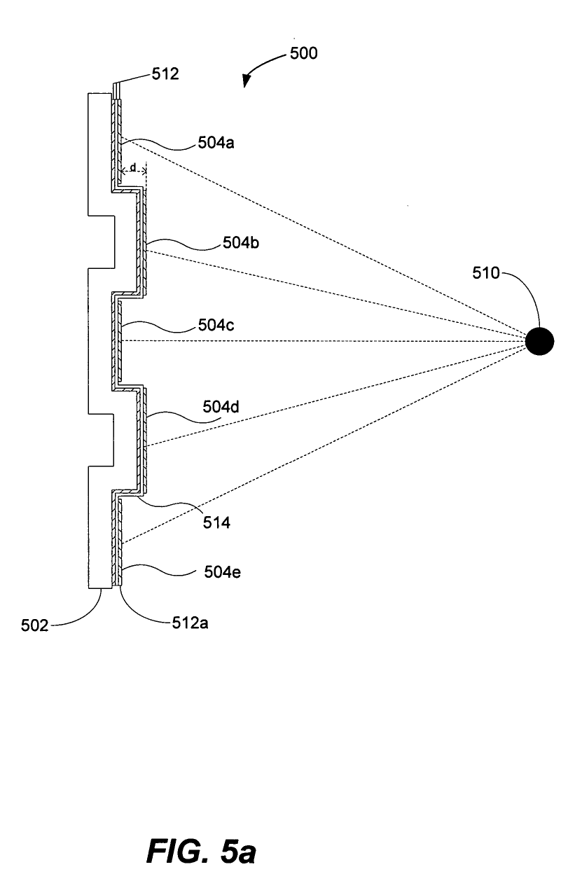

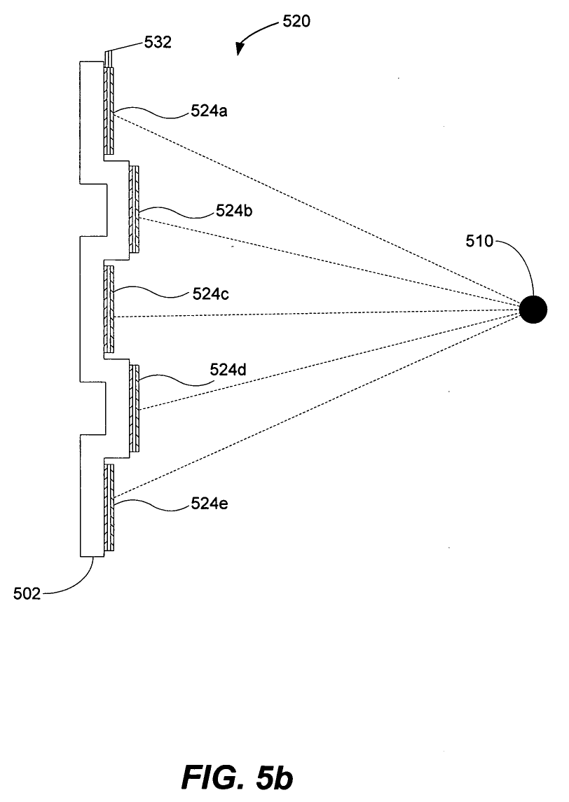

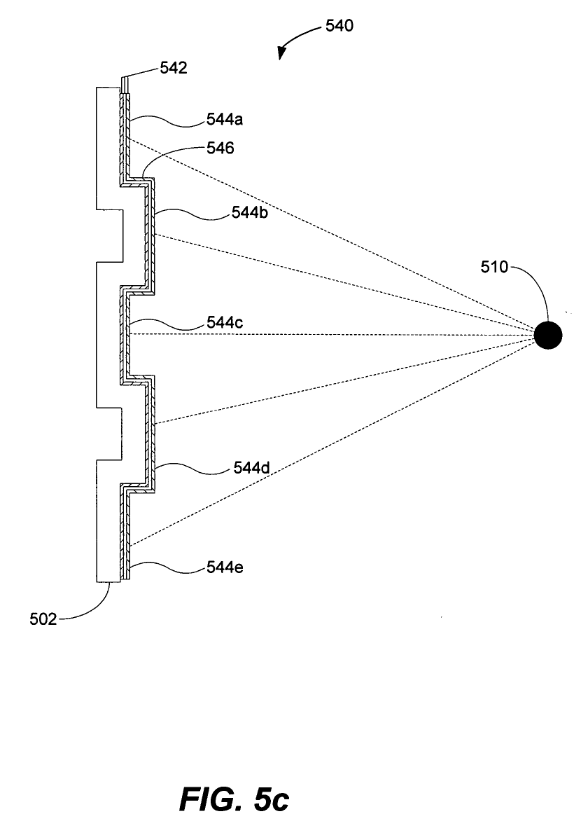

In another embodiment of the invention, as illustrated in FIGS. 5a-c, each successive outer emission zone can be positioned on a separate plane, wherein the plane of each successive outer emitting section is located at a different distance from the focalizing area than the previous interior emission zone, such that the phases of all emitted parametric waves arriving at the focalizing area will arrive within a 90° phase difference. Instead of varying the phases applied to each emission zone, as was done in FIGS. 3a and 3c, the same signal is applied to all emission zones, and the phase differentials needed to create a focalizing area 510 are created by altering the distance between each emission zone and the focalizing area. For example, in FIG. 5a, the distance ‘d’ between the 504c emission zone and the 504b and 504d emission zones will result in the waves emitted from the 504c emission zone being delayed as compared to the waves emitted from the 504b and 504d emission zones. The distance ‘d’ can be set such that the waves emitted from all emission zones 504a-e can reach the focalizing point 510, within a 90° phase difference of one another.

The exact location of the focalizing point will depend on the size of each emission zone, and the delay caused by the distance ‘d’. The distance ‘d’ may be varied such that the phase differential of the waves being emitted from the emission zones may be as great as 180° (λ2), or as small as 45° (λ8). The basic principle is that the distance from each emission zone 504a-e to the focalizing area 510 should be a multiple of the wavelength λ. For example, emission zones 504a, c, and e may represent 0° phase, while emission zones 504b and d may be one half wavelength, or 180° further from the selected focalizing area. Offsetting the distance of emission zones 504b and d by a half wavelength can enable them to arrive at the focalizing area within 90° of one another. This embodiment avoids many complexities introduced by the phase delays or inverters used in FIGS. 3a and 3c.

However, in another embodiment of the invention, it may be beneficial to combine the phase alteration techniques employed in FIGS. 3a and 3c with the separate planes employed in FIGS. 5a-d, so that phase differentials such as 45° and 90° can be created by locating the emission zones on different planes, while 180° phase differentials can be created by a simple inverting amplifier.

ESMR film is typically comprised of three layers, including two electrodes 312a and 312c and an intermediate layer of piezoelectric film (PVDF) 312b, as shown in FIG. 3b. When ESMR film is employed as the emitter, various techniques may be used to isolate each emission zone. One such embodiment is illustrated in FIG. 3b, where a single monolithic piece of film 312 is adhered to the front surface of the support member 302. Portions 314 of the forward facing conductive layer of film 312a are etched away to form separate electronically isolated emission zones 304a-g. FIG. 5a is another example where the separate emission zones 504a-e are formed by etching away portions 514 of the forward facing conductive layer of film 512a.

Alternatively, the ESMR film 312 (FIG. 3b) can be reversed such that the electrode layer 312a having the etched portions 314 is facing the support member 302. When the isolated emission zones 304a-g are facing the support member 302, the signal sources are more easily coupled to the emission zones. One method of doing so is to include a printed circuit board (PCB) on the forward facing side of the support members, wherein the PCB has electrodes which couple to the emission zones 304a-g.

In another embodiment, illustrated in FIG. 5b, each emission zone 524a-e is a completely separate piece of ESMR film 532. In this embodiment, there is no need for etching to separate the emission zones 524a-e. Each emission zone 524a-e is electronically isolated due to the distance between the zones. The electronically isolated emission zones 524a-e can be adhered to the front surface of the support member 502. The phase of each emission zone 524a-e can be adjusted to enable the speaker 520 to focus acoustical energy to a focalizing area 510. For example, each emission zone 524a-e can be 90° out-of-phase with adjacent emission zones. The dimensions of the speaker 520 can be such that the 90° phase shift will enable the acoustical energy to constructively add at the focalizing area 510.

In another embodiment, illustrated in FIG. 5c, a single monolithic piece of film 542 is adhered to the front surface of the support member 502. Unlike FIG. 5a, there are no portions that are etched away between each of the surfaces. The sideways-facing portions of film 546 are active, but the waves emitted by these portions are insignificant as compared to the forward-facing portions 544a-e. The support member 502 can be formed with dimensions enabling the zones to have a predetermined phase shift between the adjacent zones. For example, as above, the support member can be constructed with dimensions enabling a 90° phase shift to occur between each zone 544a-e and the focalizing area 510.

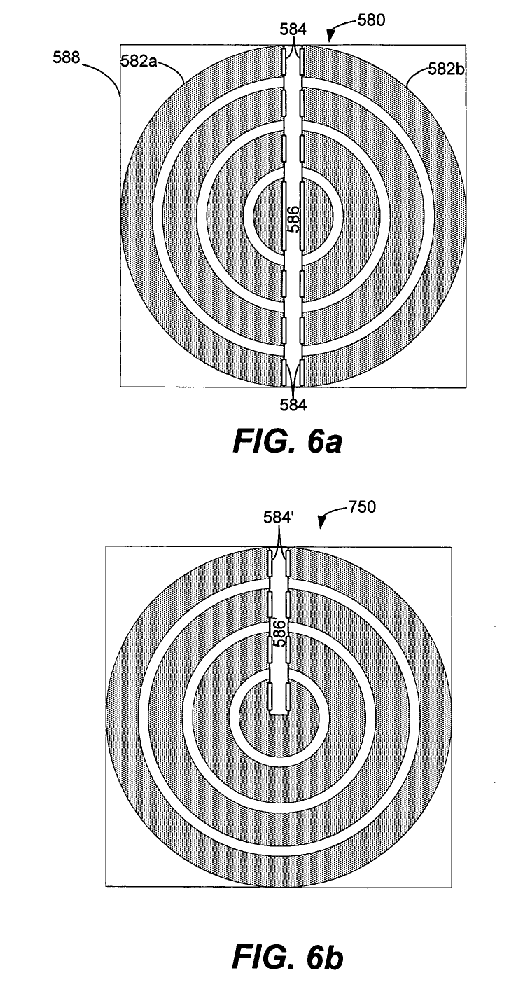

Various techniques of creating electrical contacts to the conductive portions of film may be employed. One technique, illustrated in FIG. 6a is to divide the entire piece of film in half 580, separating the film into two pieces 582a and 582b. By separating the film, electrical contacts 584 can be placed on the inner edges of the emission zones. The electrical contacts 584 may be secured in place by a thin circuit board 586 that is mounted on the support member 588, and extends the entire diameter of the ESMR film. The circuit board 586 may supply the electronic signals to the electronic contacts 584 or may merely be a routing means to connect a desired amplifier output polarity or phase to each emission zone.

Another technique of creating electrical contacts to the conductive portions of film, illustrated in FIG. 6b, is to slice away one section of film 750. Electrical contacts 584′ can then be placed on the inner edges of the conductive portions of film. The electrical contacts 584′ may be secured in place by a thin circuit board 586′ extending through the portion of ESMR film that has been sliced away.

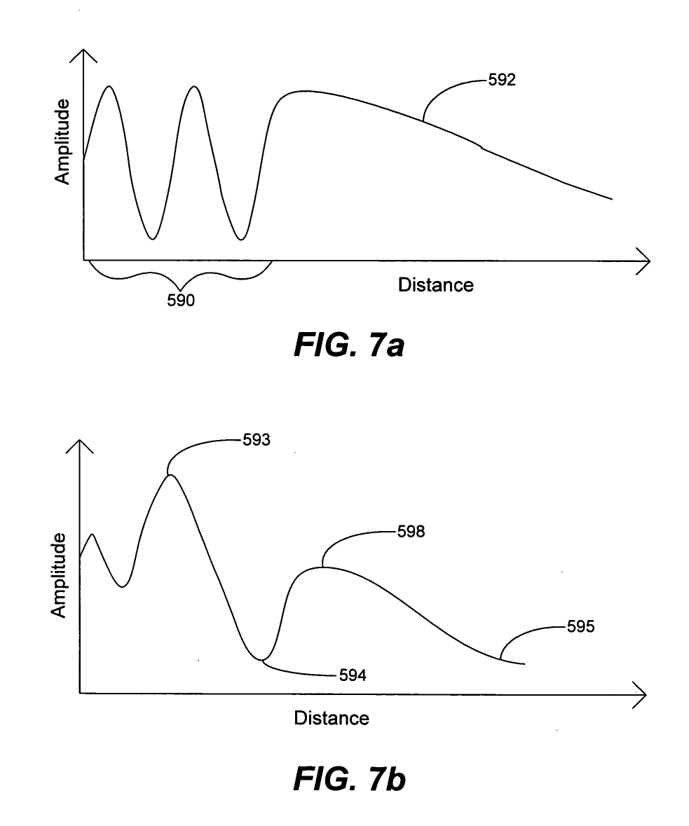

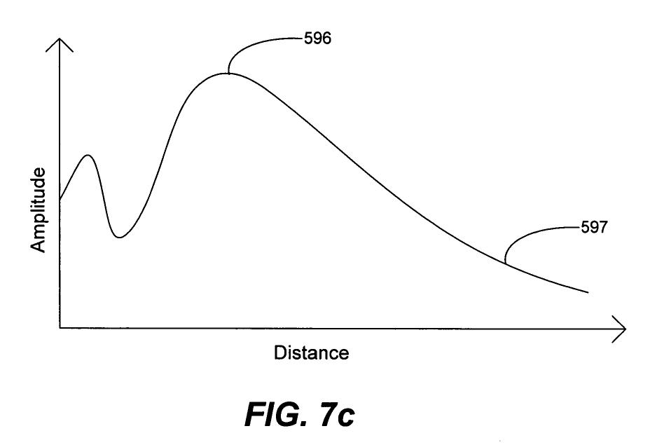

FIGS. 7a, 7b, and 7c plot approximate amplitudes of decoupled audio waves versus the distance away from the transducer for various types of parametric transducers. The exact distances will vary depending on the specifications of each individual emitter. FIG. 7a is an amplitude vs. distance plot for prior art parametric transducer. In the near field, represented as 590, the amplitude of the decoupled audio wave fluctuates, because the phases of the waves emitted from the end-fire array have not yet aligned. In the far-field 592, the phases of the parametric waves are aligned, and the amplitude of the decoupled audio wave is more consistent.

FIG. 7b is an amplitude vs. distant plot of an emitter similar to that of FIG. 3c. Note that the emitter in FIG. 3c is comprised of an even number of emission zones. When an even number of emission zones is employed, the amplitude of the decoupled audio wave will peak at the focalizing area 593. The waves will then destructively interfere and will cause the signal to become sharply attenuated at a null zone 594. The waves will then constructively interfere and cause a second, smaller peak 598 having lower amplitude than the focalizing area. As the waves reach the far field, 595, the amplitude of the decoupled audio wave will steadily decrease.

FIG. 7c is an amplitude vs. distant plot of an emitter similar to that of FIG. 3c, with the exception that the emitter is comprised of an odd number of emission zones. When an odd number of emission zones are employed, the amplitude of the decoupled audio wave will peak at the focalizing area 596. While the amplitude in the far field 597 is sharply attenuated, the attenuation is not as dramatic as the emitters having an even-number of emission zones.

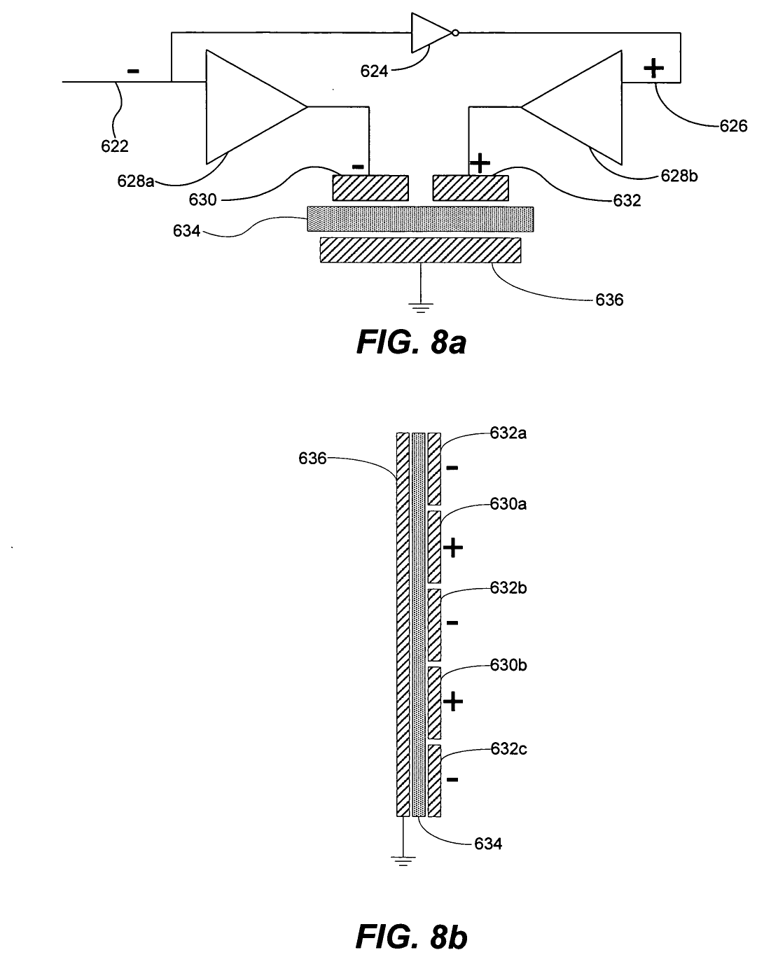

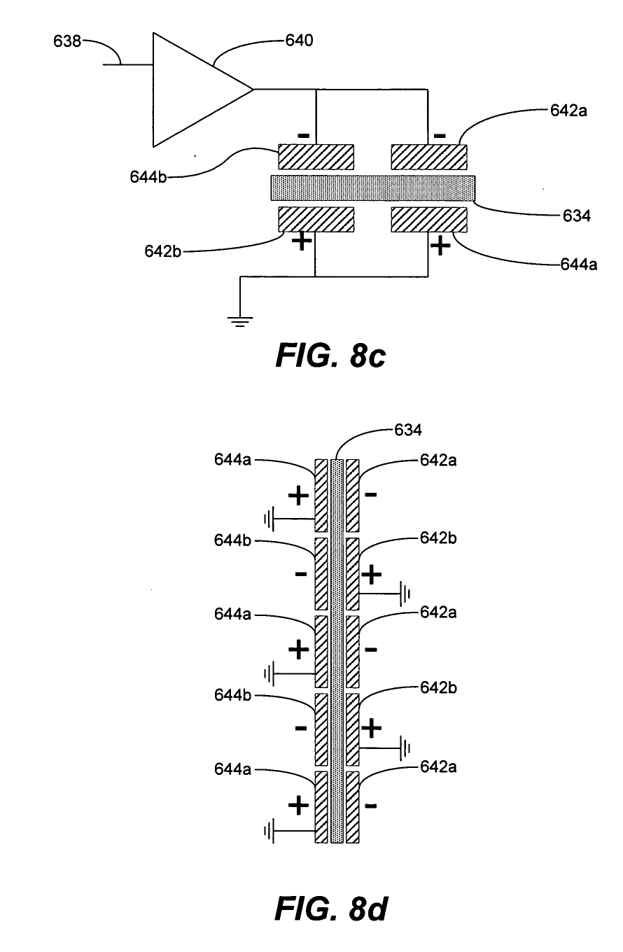

FIGS. 8a and 8b illustrate one possible embodiment for the above disclosed inventions. Specifically, FIGS. 8a and 8b may be used to implement a transducer wherein an ESMR film is used as the adjacent emission zones, and the signals driving each adjacent emission zone alternate between a phase of 0° and a phase of 180°. 0° phase is represented by a ‘−’ symbol and 180° phase is represented by a ‘+’ symbol. FIG. 8b is a more visual illustration of the ESMR film being driven by the amplifiers 628a and 628b in FIG. 8a. Like reference numerals refer to like parts in FIGS. 8a and 8b. As described above, ESMR film is comprised of three layers, including two external electrodes and an internal layer of PVDF film 634. Here, one external electrode is separated into positively 632 and negatively 630 driven emission zones. The other external electrode 636 is connected to ground. The positively driven electrodes 632 are connected to the output of the positively driven amplifier 628b. The negatively driven electrodes 630 are connected to the output of the negatively driven amplifier 628a. The positive signal is created by passing the negative signal through an inverter 624.

FIGS. 8c and 8d illustrate an alternative implementation, using ESMR film for the emission zones. Like reference numerals refer to like parts in FIGS. 8c and 8d. Instead of only separating one of the electrodes into positively and negatively driven emission zones, both of the external electrodes are separated into positively and negatively driven emission zones. The amplifier 640 alternately drives the 642 electrode and the 644 electrode. The electrodes not being driven by the amplifier are tied to ground.

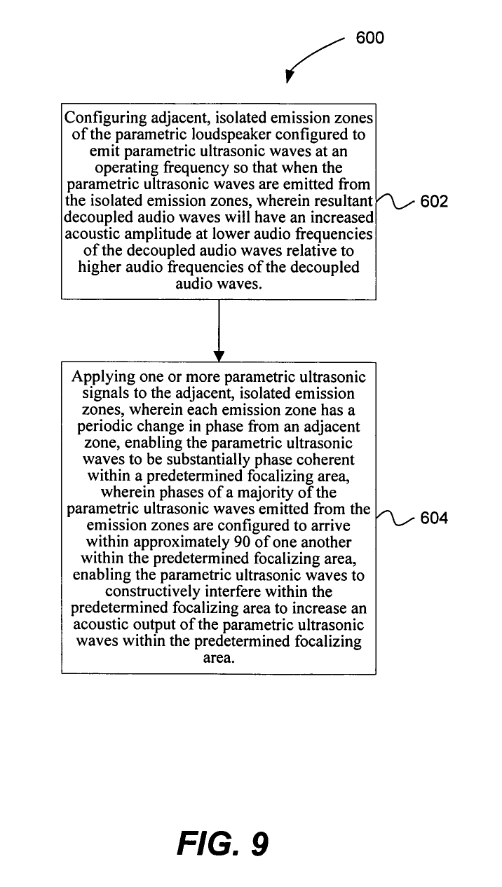

As illustrated in FIG. 9, a method 600, in accordance with the present invention, is shown for increasing acoustic amplitude at lower audio frequencies of resultant decoupled audio waves from a parametric loudspeaker. The method 600 may include configuring 602 adjacent, isolated emission zones of the parametric loudspeaker configured to emit parametric ultrasonic waves at an operating frequency so that when the parametric ultrasonic waves are emitted from the isolated emission zones, wherein resultant decoupled audio waves will have an increased acoustic amplitude at lower audio frequencies of the decoupled audio waves relative to higher audio frequencies of the decoupled audio waves. The method 600 may further include applying 604 one or more parametric ultrasonic signals to the adjacent, isolated emission zones, wherein each emission zone has a periodic change in phase from an adjacent zone, enabling the parametric ultrasonic waves to be substantially phase coherent within a predetermined focalizing area, wherein phases of a majority of the parametric ultrasonic waves emitted from the emission zones are configured to arrive within approximately 90° of one another within the predetermined focalizing area, enabling the parametric ultrasonic waves to constructively interfere within the predetermined focalizing area to increase an acoustic output of the parametric ultrasonic waves within the predetermined focalizing area.

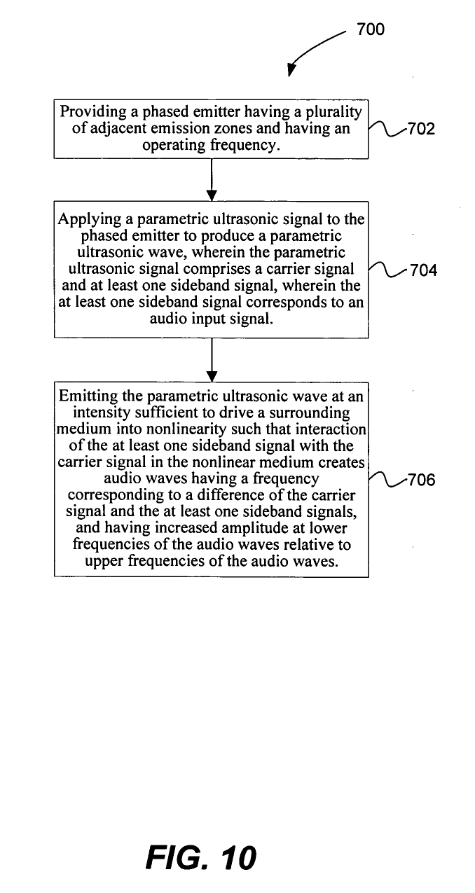

As illustrated in FIG. 10, a method 700, in accordance with the present invention, is shown for creating a wideband focalization of an audio wave. The method 700 may include providing 702 a phased emitter having a plurality of adjacent emission zones and having an operating frequency. The method 700 may further include applying 704 a parametric ultrasonic signal to the phased emitter to produce a parametric ultrasonic wave, wherein the parametric ultrasonic signal comprises a carrier signal and at least one sideband signal, wherein the at least one sideband signal corresponds to an audio input signal. The method 700 may further include emitting 706 the parametric ultrasonic wave at an intensity sufficient to drive a surrounding medium into nonlinearity such that interaction of the at least one sideband signal with the carrier signal in the nonlinear medium creates audio waves having a frequency corresponding to a difference of the carrier signal and the at least one sideband signals, and having increased amplitude at lower frequencies of the audio waves relative to upper frequencies of the audio waves.

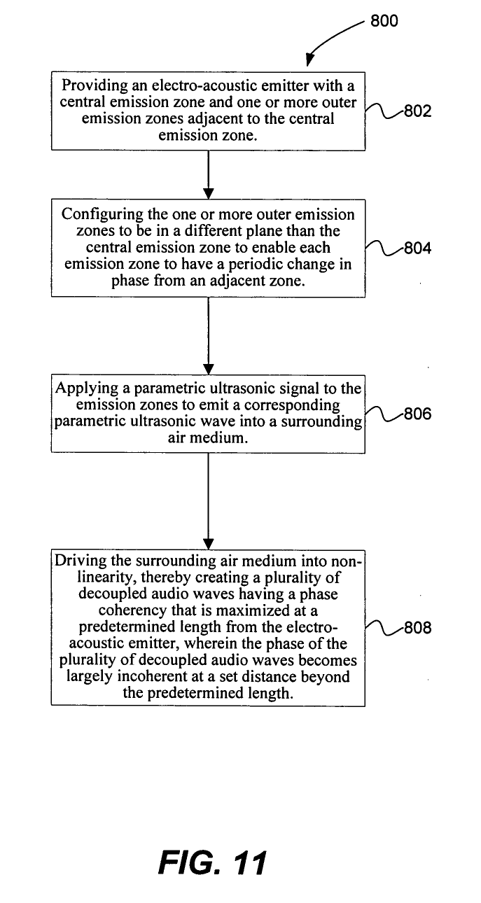

As illustrated in FIG. 11, a method 800, in accordance with the present invention, is shown for reducing length of an audio column of a parametric loudspeaker when used in an air medium. The method 800 may include providing 802 an electro-acoustic emitter with a central emission zone and one or more outer emission zones adjacent to the central emission zone. The method 800 may further include configuring 804 the one or more outer emission zones to be in a different plane than the central emission zone to enable each emission zone to have a periodic change in phase from an adjacent zone. The method 800 may further include applying 806 a parametric ultrasonic signal to the emission zones to emit a corresponding parametric ultrasonic wave into a surrounding air medium. The method 800 may further include driving 808 the surrounding air medium into non-linearity, thereby creating a plurality of decoupled audio waves having a phase coherency that is maximized at a predetermined length from the electro-acoustic emitter, wherein the phase of the plurality of decoupled audio waves becomes largely incoherent at a set distance beyond the predetermined length. One application of this method would be in situations where audible sound is needed at one predetermined area in space, but was not needed or desired at areas beyond the predetermined area.

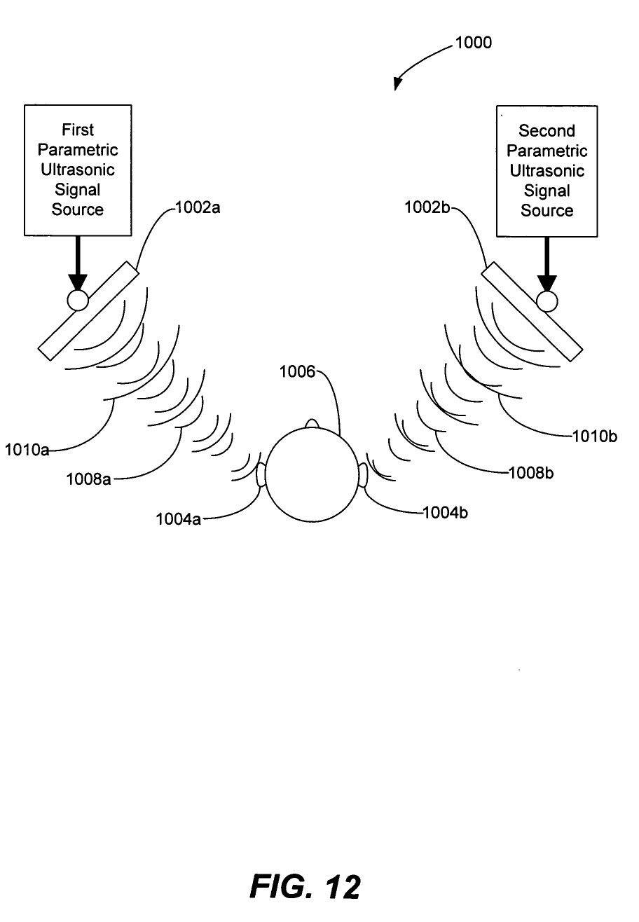

One useful embodiment of the present invention is to use the focusing capabilities of the emitter in a virtual headset application, as described in detail in copending patent application Ser. No. 10/458,498, and illustrated in FIG. 12. The focalizing emitters 1002a and 1002b are directed towards the ears 1004a and 1004b of the listener 1006. Because of the focalization capabilities of the emitters 1002a and 1002b, the emitted parametric ultrasonic waves 1010a and 1010b produce decoupled audio waves 1008a and 1008b that are each heard substantially exclusively at one ear of the listener, much like the audio produced by each individual speaker in a conventional set of headphones. It should be noted that the waves 1008a, 1008b, 1010a and 1010b are not intended to be viewed as decreasing in amplitude as they approach the ears 1004a and 1004b of the listener 1006. Instead, the illustration is intended to portray the notion that the waves are focalized at the ears of the listener, and are substantially inaudible at other locations.

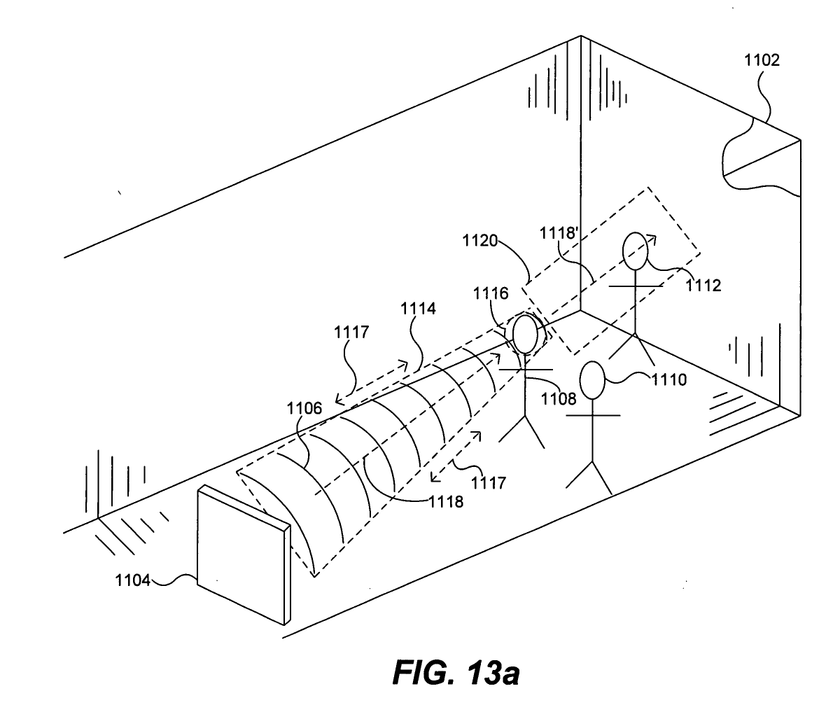

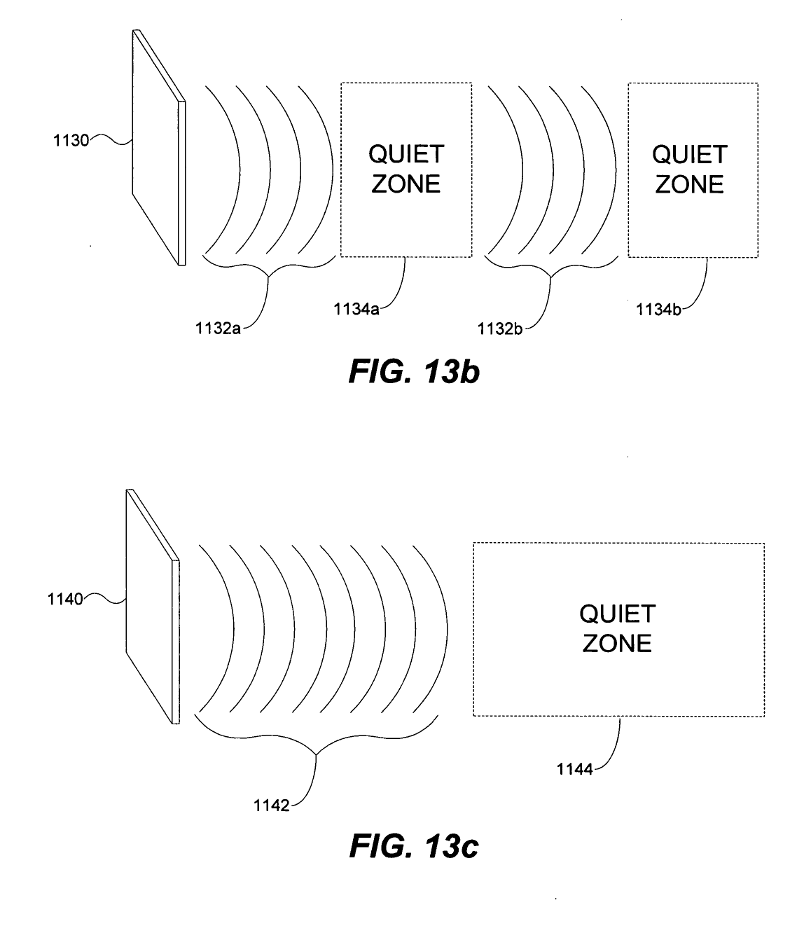

In another embodiment of the invention, illustrated in FIG. 13a, a parametric sound system is provided for creating a quiet zone along the same direction of propagation as an audible zone 1114. The predefined audible zone is defined as an area where an audible signal can be heard by a listener. In the specific example of FIG. 13a, the predefined audible zone is limited to the area within the dotted box 1114. The quiet zones are all other areas within the room 1102 that are outside the dotted box 1114. This invention allows multiple listeners to coexist within the same room 1102, wherein certain listeners 1110 and 1112 who do not wish to hear audio produced by the emitter 1104 may simply situate themselves in the quiet zones, while those listeners 1108 who do wish to hear the audio can situate themselves within the audible zone 1114. This creation of a predefined audible zone and predefined quiet zones within the same listening area is a large improvement over the prior art, because prior art speakers normally fill the entire listening area with audible sound, having a very limited amount of control as to the areas within the listening area that actually receive audible sound.

To create predefined quiet zones within the same listening area as a predefined audible zone 1114, a parametric electro-acoustic emitter 1104 is configured for emitting a focalized parametric ultrasonic wave 1106. Parametric ultrasonic signals are applied to the parametric electro-acoustic emitter 1104 with a signal source. A resultant decoupled acoustic wave is maximized at a focalizing area 1116 within the predefined audible zone 1114. The acoustic waves can be substantially in phase within the audible zone, enabling the waves to constructively interfere to increase the overall amplitude or volume of the sound within the audible zone. A signal processor may also be included. The signal processor can be used for controlling phases of the parametric ultrasonic signal so that the emitted focalized parametric ultrasonic wave will create a quiet zone along the same direction of propagation as an audible zone. The phase of the acoustic waves can be adjusted such that after the acoustic waves constructively interfere within the audible zone, the acoustic waves will become increasingly out-of-phase. At a predetermined distance from the audible zone the acoustic waves can have a phase difference approaching 180 degrees. At that point, destructive interference will substantially decrease the amplitude of the waves, creating one or more quiet zones. Thus the listener 1108 is able to enjoy a full audio experience, and listeners 1112 and 1110 are able to coexist within the same room while enjoying peace and quiet. Notably, the parametric sound system is capable of aligning the phases of the focalized parametric ultrasonic wave 1106 such that a quiet zone 1120 exists along the same direction of propagation 1118′ as the audible zone 1114. In the example of FIG. 13a, the quiet zone 1120 is created directly following, and along the same direction of propagation 1118′ as the audible zone. Thus, the audible sound created by the parametric sound system essentially stops in mid air, at the region 1120 following the listener 1108, allowing the listener 1112, who is positioned along the same direction of propagation 1118′, to avoid listening to the audio.

In one embodiment, also illustrated in FIG. 13a, quiet zones 1117 may exist in areas located along one or more sides of the direction of propagation 1118 of the parametric ultrasonic focalized wave 1106.

In another embodiment, illustrated in FIG. 13b, a quiet zone 1134a is interposed between, and along the same direction of propagation as at least two audible zones 1132a and 1132b. In addition, a second quiet zone 1134b may exist beyond the second audible zone 1132b. The audible zones 1132a and 1132b may be of nearly equal audio intensities. Alternatively, the audible zones 1132a and 1132b may produce substantially different audio intensities. FIG. 7b illustrates an amplitude vs. distance plot which shows an example where one audible zone 593 produces substantially more audio intensity than the second audible zone 598.

In another embodiment, illustrated in FIG. 13c, a quiet zone 1144 is created directly following, and along the same direction of propagation as an audible zone 1142. FIG. 7c, providing an amplitude vs. distance plot, illustrates one example where the quiet zone 597 directly follows the audible zone 596.

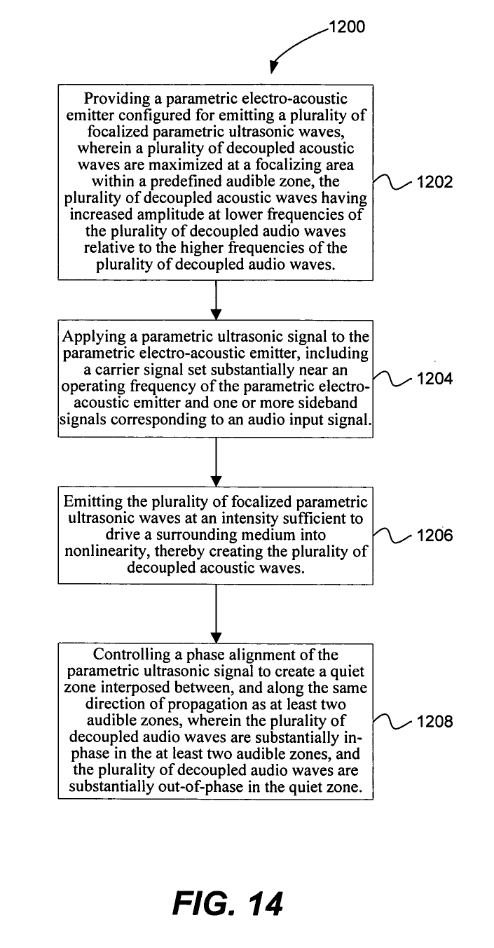

As illustrated in FIG. 14, a method 1200, in accordance with the present invention, is shown for creating a quiet zone interposed between at least two audible zones along a direction of propagation. The method 1200 may include providing 1202 a parametric electro-acoustic emitter configured for emitting a plurality of focalized parametric ultrasonic waves, wherein a plurality of decoupled acoustic waves are maximized at a focalizing area within a predefined audible zone, the plurality of decoupled acoustic waves having increased amplitude at lower frequencies of the plurality of decoupled audio waves relative to the higher frequencies of the plurality of decoupled audio waves. The method 1200 may further include applying 1204 a parametric ultrasonic signal to the parametric electro-acoustic emitter, including a carrier signal set substantially near an operating frequency of the parametric electro-acoustic emitter and one or more sideband signals corresponding to an audio input signal. The method 1200 may further include emitting 1206 the plurality of focalized parametric ultrasonic waves at an intensity sufficient to drive a surrounding medium into nonlinearity, thereby creating the plurality of decoupled acoustic waves. The method 1200 may further include controlling 1208 a phase alignment of the parametric ultrasonic signal to create a quiet zone interposed between, and along the same direction of propagation as at least two audible zones, wherein the plurality of decoupled audio waves are substantially in-phase in the at least two audible zones, and the plurality of decoupled audio waves are substantially out-of-phase in the quiet zone.

In another embodiment, a second method is provided for creating a quiet zone directly following, and along the same direction of propagation as an audible zone. The method may include providing a parametric electro-acoustic emitter configured for emitting a plurality of focalized parametric ultrasonic waves, wherein a plurality of decoupled acoustic waves are maximized at a focalizing area within the predefined audible zone, the plurality of decoupled acoustic waves having increased amplitude at lower frequencies relative to the higher frequencies of the decoupled audio waves. The method may further include applying a parametric ultrasonic signal to the parametric electro-acoustic emitter, including a carrier signal set substantially near an operating frequency of the parametric electro-acoustic emitter and one or more sideband signals corresponding to an audio input signal. The method may further include emitting the plurality of focalized parametric ultrasonic waves at an intensity sufficient to drive a surrounding medium into nonlinearity, thereby creating the plurality of decoupled audio waves. The method may further include controlling the phase alignment of the parametric ultrasonic signal to create the quiet zone directly following, and along the same direction of propagation as the audible zone, wherein the plurality of decoupled audio waves are substantially in phase in the audible zone, and the plurality of decoupled audio waves are largely out-of-phase in the predefined quiet zone.

It is to be understood that the above-referenced arrangements are illustrative of the application for the principles of the present invention. Numerous modifications and alternative arrangements can be devised without departing from the spirit and scope of the present invention while the present invention has been shown in the drawings and described above in connection with the exemplary embodiments of the invention. It will be apparent to those of ordinary skill in the art that numerous modifications can be made without departing from the principles and concepts of the invention as set forth in the examples.

1) A method for increasing acoustic amplitude at lower audio frequencies of resultant decoupled audio waves from a parametric loudspeaker, the method comprising:
a) configuring adjacent, isolated emission zones of the parametric loudspeaker configured to emit parametric ultrasonic waves at an operating frequency so that when the parametric ultrasonic waves are emitted from the isolated emission zones, wherein resultant decoupled audio waves will have an increased acoustic amplitude at lower audio frequencies of the decoupled audio waves relative to higher audio frequencies of the decoupled audio waves; and
b) applying one or more parametric ultrasonic signals to the adjacent, isolated emission zones, wherein each emission zone has a periodic change in phase from an adjacent zone, enabling the parametric ultrasonic waves to be substantially phase coherent within a predetermined focalizing area, wherein phases of a majority of the parametric ultrasonic waves emitted from the emission zones are configured to arrive within approximately 90° of one another within the predetermined focalizing area, enabling the parametric ultrasonic waves to constructively interfere within the predetermined focalizing area to increase an acoustic output of the parametric ultrasonic waves within the predetermined focalizing area.

2) The method of claim 1, further comprising the step of configuring the adjacent, isolated emission zones as a center isolated conductive emission strip and a parallel emission strip on both sides of the center isolated emission strip, the parallel emission strips being located at progressively further distances from the center isolated emission strip.

3) The method of claim 1, further comprising the more specific step of configuring the adjacent, isolated emission zones as a center isolated emission zone and at least one concentric outer-ring isolated emission zone.

4) The method of claim 1, wherein the adjacent, isolated emission zones are comprised of Electrically Sensitive and Mechanically Responsive (ESMR) film configured for emitting parametric ultrasonic waves.

5) The method of claim 1, wherein the isolated emission zones are comprised of a plurality of bimorph transducers configured for emitting parametric ultrasonic waves.

6) The method of claim 1, further comprising the step of positioning all adjacent, isolated emission zones on a single plane.

7) The method of claim 6, further comprising the step of applying the one or more parametric ultrasonic signals to a center isolated emission zone at approximately 0° phase, and incrementing a phase of the one or more parametric ultrasonic signals applied to each successive outer adjacent emission zone by approximately 180°.

8) The method of claim 6, further comprising the step of applying the one or more parametric ultrasonic signals to a center isolated emission zone at approximately 0° phase, and incrementing a phase of the one or more parametric ultrasonic signals applied to each successive outer adjacent emission zone by approximately 90°.

9) The method of claim 6, comprising the step of applying the one or more parametric ultrasonic signals to a center isolated emission zone at approximately 0° phase, and incrementing a phase of the one or more parametric ultrasonic signal applied to each successive outer adjacent emission zone by approximately 45°.

10) The method of claim 1, comprising the step of positioning at least one outer emission zone on a separate plane relative to an adjacent emission zone, wherein one or more planes of a plurality of the adjacent, isolated emission zones are located at different distances from the predetermined focalizing area, such that the phases of all emitted parametric waves are within approximately 90° within the predetermined focalizing area.

11) A parametric sound system for increasing acoustic amplitude at lower audio frequencies at a predetermined focalizing area, comprising:
a) an electro-acoustic emitter capable of emitting parametric ultrasonic waves, and having a series of adjacent, isolated emission zones;
b) a signal source for supplying parametric ultrasonic signals to each adjacent, isolated emission zone; and
c) wherein each adjacent, isolated emission zone is sized and positioned to operate at a predetermined operating frequency, and phases of each parametric ultrasonic signal applied to each emission zone are configured such that the parametric ultrasonic waves emitted from each emission zone will arrive at the predetermined focalizing area within approximately a 90° phase difference, resulting in a plurality of decoupled audio waves having increased acoustic amplitude at lower audio frequencies relative to higher audio frequencies of the decoupled audio waves.

12) The parametric sound system of claim 11, wherein the adjacent, isolated emission zones more specifically comprise a center isolated conductive emission strip and a plurality of parallel emission strips on both sides of the center isolated conductive emission strip, each of the plurality of parallel emission strips being located at progressively further distances from the center emission strip.

13) The parametric sound system of claim 11, wherein the adjacent isolated, emission zones more specifically comprise a center isolated emission zone and at least one concentric outer-ring isolated conductive emission zone.

14) The parametric sound system of claim 11, wherein the adjacent, isolated emission zones are comprised of electrically sensitive and mechanically responsive (ESMR) film configured for emitting parametric ultrasonic waves, wherein one side of the ESMR film is coupled to a support member.

15) The parametric sound system of claim 14, wherein at least one portion of an outer electrode coupled to the ESMR film is etched away to create the adjacent, isolated emission zones.

16) The parametric sound system of claim 15, wherein the outer electrode coupled to the ESMR film having at least one etched portion is facing outward from the support member.

17) The parametric sound system of claim 15, wherein the outer electrode coupled to the ESMR film having at least one etched portion is facing toward the support member.

18) The parametric sound system of claim 14, wherein each emission zone is comprised of a portion of an entire ESMR film, with etched portions between each adjacent emission zone to create the adjacent, isolated emission zones.

19) The parametric sound system of claim 14, further comprising a printed circuit board coupled to the support member, the printed circuit board having electrical contacts for coupling the signal source to each adjacent, isolated emission zone.

20) The parametric sound system of claim 11, wherein the adjacent, emission zones are comprised of a plurality of bimorph transducers configured for emitting parametric ultrasonic waves.

21) The parametric sound system of claim 11, wherein the parametric ultrasonic signal is applied to a center isolated emission zone at approximately 0° phase, and the phases applied to each successive outer adjacent emission zone are alternated between approximately 180° out-of-phase and approximately 0° out-of-phase with respect to an inner adjacent emission zone.

22) The parametric sound system of claim 11, wherein the parametric ultrasonic signal is applied to a center isolated emission zone at approximately 0° phase, and a phase of the parametric ultrasonic signal applied to each successive outer adjacent emission zone is increased by approximately 90°.

23) The parametric sound system of claim 11, wherein the parametric ultrasonic signal is applied to a center isolated emission zone at approximately 0° phase, and the phase of the parametric ultrasonic signal applied to each successive outer adjacent emission zone is increased by approximately 45°.

24) The parametric sound system of claim 11, further comprising a switch for disabling phase differentials of the parametric ultrasonic signals applied to each emission zone such that all signals are applied at approximately 0° phase differential, thereby creating a parametric ultrasonic wave that is not focalized to the predetermined focalizing area.

25) The parametric sound system of claim 24, more specifically comprising a fading switch for gradually switching the parametric ultrasonic wave between a focalized wave and a non-focalized wave.

26) A parametric sound system for increasing amplitude at lower audio frequencies, comprising:
a) an electro-acoustic emitter capable of emitting parametric ultrasonic waves, and having at least a center circular isolated emission zone and one or more concentric outer-ring isolated emission zone;
b) a signal source for supplying a parametric ultrasonic signal to each of the one or more isolated emission zone;
c) wherein radii of outer and inner bounds of each of the one or more isolated emission zones are constructed to operate at a predetermined operating frequency; and
d) wherein the parametric ultrasonic waves decouple to produce acoustic waves, wherein the acoustic waves have an increased acoustic amplitude at lower acoustic frequencies relative to higher frequencies of the acoustic waves.

27) A parametric sound system for focalizing a parametric ultrasonic wave, comprising:
a) an electro-acoustic emitter capable of emitting parametric ultrasonic waves, and having a plurality of isolated emission zones comprising a center circular isolated emission zone and at least one concentric outer-ring isolated emission zone;
b) a signal source for supplying a parametric ultrasonic signal to each isolated emission zone wherein each emission zone has a periodic change in phase from an adjacent zone;
c) wherein location of a focalizing area is a function of the phase of each emission zone and a radius of outer and inner bounds of each of the isolated emission zones; and
d) wherein the radius of each of the isolated emission zones are sized such that all emitted parametric waves will arrive at the focalizing area within approximately a 90° range with respect to the phase of other parametric waves in the focalizing area.

28) A method for creating a wideband focalization of an audio wave, comprising:
a) providing a phased emitter having a plurality of adjacent emission zones and having an operating frequency;
b) applying a parametric ultrasonic signal to the phased emitter to produce a parametric ultrasonic wave, wherein the parametric ultrasonic signal comprises a carrier signal and at least one sideband signal, wherein the at least one sideband signal corresponds to an audio input signal; and
c) emitting the parametric ultrasonic wave at an intensity sufficient to drive a surrounding medium into nonlinearity such that interaction of the at least one sideband signal with the carrier signal in the nonlinear medium creates audio waves having a frequency corresponding to a difference of the carrier signal and the at least one sideband signals, and having increased amplitude at lower frequencies of the audio waves relative to upper frequencies of the audio waves.

29) The method of claim 28, further comprising setting the carrier frequency approximately at the operating frequency for increased energy efficiency at the carrier frequency.

30) The method of claim 28, further comprising offsetting the operating frequency from a resonant frequency of a plurality of phased emitters by a predetermined frequency amount to an offset operating frequency to increase output efficiency at the offset operating frequency.

31) A method for reducing length of an audio column of a parametric loudspeaker when used in an air medium, comprising:
a) providing an electro-acoustic emitter with a central emission zone and one or more outer emission zones adjacent to the central emission zone;
b) configuring the one or more outer emission zones to be in a different plane than the central emission zone to enable each emission zone to have a periodic change in phase from an adjacent zone;
c) applying a parametric ultrasonic signal to the emission zones to emit a corresponding parametric ultrasonic wave into a surrounding air medium; and
d) driving the surrounding air medium into non-linearity, thereby creating a plurality of decoupled audio waves having a phase coherency that is maximized at a predetermined length from the electro-acoustic emitter, wherein the phase of the plurality of decoupled audio waves becomes largely incoherent at a set distance beyond the predetermined length.

32) A method for creating a quiet zone interposed between at least two audible zones along a direction of propagation, comprising:
a) providing a parametric electro-acoustic emitter configured for emitting a plurality of focalized parametric ultrasonic waves, wherein a plurality of decoupled acoustic waves are maximized at a focalizing area within a predefined audible zone, the plurality of decoupled acoustic waves having increased amplitude at lower frequencies of the plurality of decoupled audio waves relative to the higher frequencies of the plurality of decoupled audio waves;
b) applying a parametric ultrasonic signal to the parametric electro-acoustic emitter, including a carrier signal set substantially near an operating frequency of the parametric electro-acoustic emitter and one or more sideband signals corresponding to an audio input signal;
c) emitting the plurality of focalized parametric ultrasonic waves at an intensity sufficient to drive a surrounding medium into nonlinearity, thereby creating the plurality of decoupled acoustic waves; and
d) controlling a phase alignment of the parametric ultrasonic signal to create a quiet zone interposed between, and along the same direction of propagation as at least two audible zones, wherein the plurality of decoupled audio waves are substantially in-phase in the at least two audible zones, and the plurality of decoupled audio waves are substantially out-of-phase in the quiet zone.

33) The method of claim 32, comprising the more specific step of providing a parametric electro-acoustic emitter configured for emitting a plurality of focalized parametric ultrasonic waves, having a central circular isolated emission zone and at least one concentric outer-ring isolated emission zone.

34) The method of claim 33, comprising the more specific step of providing a parametric electro-acoustic emitter configured for emitting a plurality of focalized parametric ultrasonic waves, having a central circular isolated emission zone and at least one concentric outer-ring isolated emission zone, wherein there is an even number of emission zones.

35) A method for creating a quiet zone directly following, and along a same direction of propagation as an audible zone, comprising:
a) providing a parametric electro-acoustic emitter configured for emitting a plurality of focalized parametric ultrasonic waves, wherein a plurality of decoupled acoustic waves are maximized at a focalizing area within a predefined audible zone, the plurality of decoupled acoustic waves having increased amplitude at lower frequencies of the plurality of decoupled acoustic waves relative to the higher frequencies of the plurality of decoupled acoustic waves;
b) applying a parametric ultrasonic signal to the parametric electro-acoustic emitter, including a carrier signal set substantially near an operating frequency of the parametric electro-acoustic emitter and one or more sideband signals corresponding to an audio input signal;
c) emitting the plurality of focalized parametric ultrasonic waves at an intensity sufficient to drive a surrounding medium into nonlinearity, thereby creating the plurality of decoupled acoustic waves; and
d) controlling a phase alignment of the parametric ultrasonic signal to create the quiet zone directly following, and along the same direction of propagation as the audible zone, wherein the plurality of decoupled acoustic waves are substantially in phase in the audible zone, and the plurality of decoupled acoustic waves are substantially out-of-phase in the quiet zone.

36) The method of claim 35, comprising the more specific step of providing a parametric electro-acoustic emitter configured for emitting a plurality of focalized parametric ultrasonic waves, having a central circular isolated emission zone and at least one concentric outer-ring isolated emission zone.

37) The method of claim 36, comprising the more specific step of providing a parametric electro-acoustic emitter configured for emitting a plurality of focalized parametric ultrasonic waves, having a central circular isolated emission zone and at least one concentric outer-ring isolated emission zone, wherein there is an odd number of emission zones.

38) A parametric sound system for creating a quiet zone along a same direction of propagation as an audible zone, comprising:
a) a parametric electro-acoustic emitter configured for emitting a plurality of focalized parametric ultrasonic waves, wherein a plurality of decoupled acoustic waves are maximized at a focalizing area within the audible zone, the plurality of decoupled acoustic waves having increased amplitude at lower frequencies of the decoupled audio waves relative to higher frequencies of the decoupled audio waves;
b) a signal source for applying a parametric ultrasonic signal to the parametric electro-acoustic emitter, wherein the parametric ultrasonic signal includes an ultrasonic carrier signal and one or more sideband signals corresponding to an audio input signal; and
c) a signal processor for controlling phases of the parametric ultrasonic signal so that the plurality of focalized parametric ultrasonic waves emitted by the parametric electro-acoustic emitter will create a quiet zone along the same direction of propagation as the audible zone, wherein the plurality of decoupled audio waves are substantially in phase within the audible zone, and the plurality of decoupled audio waves are largely out-of-phase within the quiet zone.

39) The parametric sound system of claim 38, more specifically comprising a signal processor for controlling phases of the parametric ultrasonic signal so that the plurality of focalized parametric ultrasonic waves will create a quiet zone interposed between, and along the same direction of propagation as at least two audible zones, wherein the plurality of decoupled audio waves are substantially in phase within the at least two audible zones, and the plurality of decoupled audio waves are largely out-of-phase within the quiet zone.

40) The parametric sound system of claim 38, more specifically comprising a signal processor for controlling phases of the parametric ultrasonic signal so that the plurality of focalized parametric ultrasonic waves will create a quiet zone directly following, and along the same direction of propagation as the audible zone, wherein the plurality of decoupled audio waves are substantially in phase within the audible zone, and the plurality of decoupled audio waves are largely out-of-phase within the quiet zone.

41) A parametric sound system configured for creating a plurality of focalized decoupled audio waves, comprising:
a) an electro-acoustic emitter configured for emitting a plurality of ultrasonic wave-fronts including carrier wave components at a carrier wave frequency and sideband wave components at a sideband wave frequency, wherein phases of all carrier wave components arriving at a focalizing area are substantially aligned, and wherein the sideband wave components at frequencies near the carrier wave frequency arrive at the focalizing area having greater phase alignment and greater amplitude than the sideband wave components at frequencies that depart from the carrier wave frequency; and
b) a signal source configured for driving the electro-acoustic emitter at a level sufficient for the plurality of ultrasonic wave fronts to drive a surrounding medium into nonlinearity such that interaction of the sideband wave components with the carrier wave components creates the plurality of decoupled, focalized audio waves having maximized phase coherency at the focalizing area and having an audible frequency corresponding to a difference between the carrier wave frequency and the sideband wave frequency, and the plurality of decoupled, focalized acoustic waves having increased amplitude at lower frequencies relative to higher frequencies of the plurality of decoupled, focalized acoustic waves due to a greater phase alignment in the focalizing area of the plurality of decoupled audio waves at frequencies near the carrier wave frequency.
